(19) United States
(12) Patent Application Publication
(10) Pub. No.: US 2025/0360561 A1
(43) Pub. Date: Nov. 27, 2025

(54) ALLOYS AND METHODS OF SYNTHESIS THEREOF

(71) Applicant: The Regents of the University of California, Oakland, CA (US)

(72) Inventors: Haimei Zheng, Berkeley, CA (US); Qiubo Zhang, Albany, CA (US); Yi Chen, Berkeley, CA (US)

(21) Appl. No.: 19/217,879

(22) Filed: May 23, 2025

Related U.S. Application Data
(60) Provisional application No. 63/651,592, filed on May 24, 2024.

(51) Int. Cl. B22F 9/24; C22C 1/04; C22C 5/04; C22C 9/00

(52) U.S. Cl. CPC B22F 9/24; C22C 1/0425; C22C 1/0466; C22C 5/04; C22C 9/00; B22F 2301/10; B22F 2301/25; B22F 2998/10; B22F 2999/00

(57) ABSTRACT

Methods of producing an alloy is provided. The methods involve can liquid-liquid interfaces reactions between gallium (Ga) or a liquid metal alloy and metal precursors. The resulting high entropy states are kinetically trapped by isothermal solidification. The methods can produce alloys with increased composition diversity (e.g., above about 20 elements), different morphology (e.g., 0-dimension, 2-dimension, 3-dimension), and crystallinity variations (e.g., single crystal, polycrystalline, mesocrystal, amorphous) under mild conditions (e.g., about room temperature to 80° C.). Alloys produced by the methods, high entropy mesocrystal alloys, and Ga-free high entropy alloys are also provided.

### RELATED APPLICATIONS

This application claims priority to U.S. Provisional Application No. 63/651,592, filed on May 24, 2024, the content of which is incorporated herein by reference in its entirety.

### STATEMENT OF GOVERNMENT SUPPORT

This invention was made with government support under Contract No. DE-AC02-05CH11231 awarded by the U.S. Department of Energy. The government has certain rights in this invention.

### BACKGROUND

High entropy alloy (HEA) nanomaterials, with more than five metal elements mixed together, have potential applications ranging from catalysis to batteries. Because of the thermodynamic immiscibility of certain metal elements, some combinations of elements cannot form high entropy alloy states. Therefore, non-equilibrium methods have been developed to kinetically trap the high entropy states. For example, effective mixing of different elements can be achieved at high temperatures, followed by subsequent fast cooling such that the high entropy phase can be trapped at room temperature. However, HEAs often retain the spherical shape inherited from their melting states, exhibiting either single-crystalline or amorphous structure depending on the cooling rate. These constraints limit their application in surface reaction-related and structure-related fields.

Developing a general strategy that can precisely control elemental composition, morphology, and crystallinity of HEAs under mild conditions is challenging. Wet-chemistry approaches provide versatility of particle sizes, morphologies, and structures at low temperatures. However, wet-chemistry methodologies can only be applied to specific systems, proving unsuitable for immiscible elemental combinations. To date, innovative approaches remain to be explored to overcome the limitations imposed by these techniques.

### SUMMARY

Embodiments described herein include a general route to controllable synthesis of alloys with controlled crystallinity (single crystal, polycrystal, mesocrystal, amorphous), various morphology (0-dimension, 2-dimension, 3-dimension), and increased composition diversity (above about 20 elements) under mild conditions (about room temperature to 80° C.). In embodiments provided herein, gallium (Ga) or a liquid metal alloy, acting as metal solvents, effectively blend the metal elements. The resulting high entropy states are kinetically trapped by isothermal solidification instead of rapid cooling. The method is also applicable to other liquid-liquid interfaces reactions, such as the oil-water interface.

High entropy materials provided by the methods provided herein include hierarchical morphology HEAs, mesocrystal HEAs, and high entropy metal glasses. They possess properties that make them suitable for use in catalysis, electronics, thermoelectricity, mechanics, and other fields.

Compared with existing methods for HEAs synthesis, the method does not require complex equipment, and the reaction can be completed within about 1 minute at low temperature (e.g., about room temperature to 80° C.), significantly reducing the cost of synthesizing high entropy nanoparticles. The produced nanoparticles have rich reaction sites and ultra-strong strength and hardness, making them suitable for use as catalytic, electronic, energy, and anti-corrosion materials.

In one aspect, a method of producing an alloy is provided. The method includes providing gallium or gallium alloy particles in a liquid state; and contacting the gallium or gallium alloy particles with a metal salt solution of one or more metal precursors, thereby initiating a reaction to produce an alloy.

In some embodiments, the gallium or gallium alloy particles are loaded on a substrate. In some embodiments, the substrate is a carbon substrate. In some embodiments, the metal salt solution comprises HCl.

In some embodiments, the reaction comprises isothermal solidification. In some embodiments, the reaction is conducted at a temperature of about 25° C. to about 80° C. In some embodiments, the reaction is conducted at about 40° C., at about 60° C., or at about 80° C.

In some embodiments, the reaction is conducted for about 1 minute to 3 minutes.

In some embodiments, the gallium or gallium alloy particles are nanoparticles.

In some embodiments, the one or more metal precursors are HₓMCl_{y}, wherein M is a metal. In some embodiments, the metal (M) of the one or more metal precursors comprise at least 2, 3, 4, 5, 6, 7, 8, or 9 different metals selected from the group consisting of K, V, Cr, Mn, Fe, Co, Ni, Cu, Zn, Ru, Rh, Nd, Cd, In, Sn, Sb, Cs, Nd, Re, Pt, Au, and Pb. In some embodiments, the one or more metal precursors consist essentially of Cu, Pb, Pd, Pt, and Au.

In some embodiments, the alloy comprises a high entropy alloy (HEA). In some embodiments, the HEA comprises GaCuPdPtAuPb, GaCuPbZnAuFeCoAl, or AiFeCuPtZnPbInSnPdAuGa. In some embodiments, the alloy does not comprise Ga. In some embodiments, the alloy is about 5 nanometers to 1 micron in size.

In some embodiments, the alloy comprises a single crystal, comprises a mesocrystal, is polycrystalline, or is amorphous.

In some embodiments, the method further includes adjusting the reaction temperature, the reaction kinetics, the interface between the gallium or gallium alloy particles and the metal salt solution, or the composition of the gallium or gallium alloy particles or the metal salt solution, to adjust the elemental composition, the size, the crystallinity, or the morphology of the alloy.

In some embodiments, provided herein is an alloy produced by the methods of the present disclosure.

In one aspect, a high entropy alloy comprising a high entropy mesocrystal, a two dimensional sheet, a fiber sheet, or a high entropy metal glass is provided. In one aspect, a high entropy alloy free of gallium (Ga) is provided.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A-1F depict principles of isothermal solidification synthesis of HEA at low temperatures. FIG. 1A schematically depicts HEA synthesis via isothermal solidification achieved through a liquid-liquid interface reaction. FIG. 1B depicts thermodynamically informed design map. FIG. 1C depicts phase diagram of a representative Cu—Ga binary alloy, demonstrating two solidification routes. The rapid cooling solidification may kinetically trap the high temperature states to form HEAs (indicated by the red arrow). For isothermal solidification, the high-entropy states of liquid alloy can be trapped by rapid changing the composition at low temperatures (as highlighted by the blue arrow). FIG. 1D depicts scanning transmission electron microscopy (STEM) elemental mapping of a representative Ga—Cu alloy. FIG. 1E depicts STEM elemental mapping of a representative Pd—Cu alloy. FIG. IF depicts STEM elemental maps, HRTEM image, and fast Fourier transform (FFT) pattern of an individual HEA-NP, showing the formation of a solid-solution structure by isothermal solidification synthesis at 60° C.

FIGS. 2A-2D depict transmission electron microscopy (TEM) characterization of Ga nanoparticles. FIG. 2A depicts a low-magnification STEM image reveals the size characteristics of Ga nanoparticles. FIG. 2B depicts the HRTEM image, along with the corresponding FFT pattern of the Ga nanoparticle, indicates its amorphous structure. FIG. 2C depicts a STEM-EDS spectrum of a Ga nanoparticle confirms the presence of Ga and O elements, with Cu signals originating from the supporting Cu grid. FIG. 2D depicts STEM-EDS mapping of a Ga nanoparticle: HAADF image, Ga-Kα map, O map, and Ga-Kα&O map. The presence of O exclusively distributed on the shell part demonstrates the existence of an oxide shell.

FIGS. 3A-3B depict EDS characterization of a GISZ nanoparticle. FIG. 3A depicts the STEM-EDS mapping of a GISZ nanoparticle including HAADF image, Ga-Kα map, In-Lα map, Sn-Lβ map, Zn-Kα map, O map, and Ga-Kα&O map. The presence of O exclusively distributed on the shell part demonstrates the existence of an oxide shell. FIG. 3B depicts the STEM-EDS spectrum of a GISZ nanoparticle confirms the presence of Ga, In, Sn, Zn, and O elements, with Cu signals attributed to the underlying Cu grid.

FIG. 4 schematically depicts nucleation rate as a function of temperature. Ti is the liquid temperature.

FIGS. 5A-5E depict Mechanisms of isothermal solidification for the formation of HEA-NPs revealed through in situ liquid-phase TEM at 60° C. FIG. 5A schematically depicts HEA-NP formation, illustrating the steps of H₂ nucleation, metal incorporation, incorporation of metal elements, and crystallization. FIG. 5B depicts sequential in situ TEM images capture the formation of a HEA-NP (GaInSnZnCu) within a liquid environment at 60° C. Yellow arrows highlight H₂ bubble nucleation and growth, while the indigo arrow indicates the stirring direction of the liquid metal alloy. FIG. 5C depicts projected areas of the metal alloy and bubbles over time. Intervals I, II, and III represent stages in the dynamic process. Data are presented as mean ±standard deviation (s.d.), based on 3 independent measurements (n=3), with error bars representing s.d. FIG. 5D depicts high-resolution TEM images show structural features of the same area before and after solidification of the liquid metal alloy, corresponding to the blue and yellow squares in FIG. 5B. FIG. 5E depicts the EDS mapping revealing the elemental distribution within the synthesized HEA-NP.

FIGS. 6A-6D depict structural fluctuations during the nucleation of liquid alloy crystals. FIG. 6A depicts sequential images illustrate the fluctuations in alloy nucleation. The amorphous regions are highlighted by blue, while the yellow color indicates the crystalline regions. FIG. 6B depicts the HRTEM images of the white square area show the specific structures during the transformations. FIG. 6C depicts maximum intensity of the FFT image as a function of time, with signals from a carbon film area indicating the background noise levels (negative control) of this analysis, measured in arbitrary units (a.u.). FIG. 6D depicts nanocrystal area changes over time. The gray arrows point out the moments of amorphization.

FIGS. 7A-7E depict the controlled synthesis of HEA-NPs with various crystallinity and morphology. FIG. 7A depicts STEM images of synthesized HEA-NPs (GaPtPdPbAuCu) obtained at different temperatures and concentrations of metal ion precursors: 40° C., 0.1 M; 60° C., 0.1 M; 80° C., 0.1 M; and 40° C., 0.2 M. b-e, High-resolution TEM images, along with corresponding FFT patterns and EDS mappings, depict representative HEA-NPs synthesized under the following conditions: 40° C. with 0.1 M metal salt concentration (FIG. 7B), 60° C. with 0.1 M metal salt concentration (FIG. 7C), 80° C. with 0.1 M metal salt concentration (FIG. 7D), and 40° C. with 0.2 M metal salt concentration (FIG. 7E).

FIG. 8 depicts TEM characterization of HEA with phase separation. STEM-EDS mapping of the heterostructured HEA nanoparticle includes HAADF imaging along with elemental maps: Ga—L, Cu-Kα, Pd—L, Pt-Lβ, Au—L, Pb-Lβ, and a combined Ga—L & Pd—L map. The EDS mapping reveals a non-uniform elemental distribution within the nanoparticles, with the Ga—L & Pd—L maps highlighting the distinct phase segregation.

FIGS. 9A-9D depict TEM characterization of a mesocrystal HEA-NP (corresponding to FIG. 7C). FIG. 9A depicts a low-magnification TEM image reveals a large, porous spherical particle composed of numerous smaller nanoclusters. FIG. 9B depicts an enlarged view of the mesocrystal structure. FIG. 9C depicts pseudo-color image of FIG. 9B. FIG. 9D depicts the corresponding FFT pattern indicates that the crystalline domains are not perfectly aligned, indicating the lattice misalignment.

FIGS. 9E-9F depict EDS characterization of a mesocrystal HEA-NP (GaCuPtPbAuPd) corresponding to FIG. 9C. FIG. 9E depicts EDS mapping shows the C, O and Cl elemental distribution. The results indicate that these elements are not distributed within the particle but rather originate from the background or are absorbed on the particle's surface. FIG. 9F depicts the EDS spectrum of the HEA nanoparticle reveals the presence of C, O, Cu, Ga, Pt, Au, Pb, Pd, Al, Fe, Zr and Cl elements. C, O, and Cl come from carbon supporting film and residual salt. Al comes from Al washer, Fe from the pole piece, and Zr comes from the EDS detector.

FIG. 9G depicts XRD pattern of mesocrystal HEA-NPs (GaPtPdPbAuCu).

FIGS. 10A-10E depict characterization of mesocrystal HEA nanosheets. FIG. 10A depicts a low-magnification STEM image highlights the 2D morphology of the HEA nanosheets. FIG. 10B depicts the HRTEM image reveals their mesocrystal structure, with individual single crystalline domains exhibiting parallel crystallographic alignment while remaining spatially separated. FIG. 10C depicts an IFFT image of the HRTEM emphasizes the distinct, separated crystal domains. FIG. 10D depicts the corresponding FFT pattern indicates that the crystalline domains are not perfectly aligned, showing signs of rotational misalignment. FIG. 10E depicts EDS maps demonstrate that the elements are uniformly distributed throughout the nanosheets.

FIGS. 11A-11B depict EDS characterization of the HEA-NP using Galinstan precursor at 40° C. FIG. 11A depicts STEM-EDS mapping of the HEA-NP: HAADF image, Ga-Kα map, Cu-Kα map, Ni-Kα map, In-Lα map, Pt-Lβ map, Au-Lα map, Pd—L map, Sn-Lβ map, and Cl—K map. The EDS mapping reveals uniform elemental distribution within the nanoparticle. Cl does not belong to the HEA composition. FIG. 10B depicts the EDS spectrum of the HEA nanoparticle reveals the presence of C, O, Ga, Cu, Ni, In, Pt, Au, Pd, and Cl elements. C, O, and Cl originate from the carbon supporting film and residual salts.

FIGS. 12A-12D depict structural analysis of hierarchical HEAs. FIG. 12A depicts a TEM image of the basic flower structure. FIG. 12B depicts HRTEM showing the amorphous structure. FIG. 12C depicts the corresponding FFT in FIG. 12B. FIG. 12D depicts EDS maps of the 3D hierarchical nanostructures show its elemental distribution.

FIGS. 13A-13C depict the isothermal solidification method is efficacious for synthesizing HEA nanomaterials with controlled elemental composition, morphology, and crystallinity. FIG. 13A depicts elemental maps show HEA nanomaterials can incorporate as many as 20 metal elements. FIG. 13B depicts HEA nanomaterials with diverse shapes and morphologies can be obtained through liquid interface reactions. FIG. 13C schematically depicts the controllable crystallinity (single crystal, mesocrystalline, polycrystalline, and amorphous structures) of synthesized HEA nanomaterials.

FIGS. 14A-14B depict TEM characterization of HEA with 20 elements (correspond to FIG. 5a). FIG. 14A depicts HRTEM image showing the crystal structure of the HEA-NPs. FIG. 14B depicts the corresponding FFT pattern showing its mesocrystal structure.

FIGS. 15A-15E depict configuration analysis of some 3D hierarchical HEAs. In FIGS. 15A-15C, the 3D HEA structure is in the shape of “grape bunchs.” FIG. 15A depicts flower structure of the basic building block. FIG. 15B depicts the flower structures aligning together to form chain. Yellow dashed lines highlight the chain structure. FIG. 15C depicts chain-like structures coming together to form large “grape bunch” structure. FIG. 15D depicts the 3D HEA structure in the shape of in the shape of feathers. FIG. 15E depicts The 3D HEA structure with the shape of plum blossoms.

FIGS. 16A-16D depict morphology diagram of HEA nanomaterials. STEM images show the diverse morphology of HEAs. FIG. 16A depicts an HEA synthesized at the reaction temperature of room temperature to 30° C. The synthesis conditions for the particles depicted in FIGS. 16B-16D mirror those in panel FIG. 16A, but with elevated reaction temperatures of 40° C., 60° C., and 80° C., respectively.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

A “high entropy alloy” or “HEA” as used herein refers to alloys containing several metal elements, such as 5 or more principal elements. HEA can contain each of the metal elements in equal or approximately equal atomic proportions, or atomic percentage of between about 5% and about 35%. The inclusion of multiple elements can result in a complicated structure and high entropy effect, which bring about HEA's unique physical and mechanical properties compared with conventional alloys, which typically contain three or less metal elements in varying proportions.

One challenge in the synthesis of HEAs is the efficient incorporation of immiscible elements to a high entropy state while maintaining tunability of the morphology and crystallinity. In addition, conventional synthesis methods often necessitate high temperatures to achieve thorough mixing of elements and subsequent capture of high entropy states through quench, which requires complex equipment and significant energy consumption. In contrast, embodiments described herein include an isothermal solidification strategy for synthesis of HEAs at low temperature, e.g., from room temperature (RT) to 80-90° C. By directing the metal ion reduction reactions to the interfaces between the Ga or Ga-based liquid metal and an aqueous salt solution, HEAs can be formed with remarkable control of crystallinity, morphology and structure, including those with intrinsically immiscible metal element combinations. The isothermal solidification of HEAs marks a breakthrough in HEA synthesis, providing a superior process to rapid cooling for trapping the liquid alloy states. HEAs prepared by the methods provided herein can have unique structures and features.

### A. Tuning the Morphology, Crystallinity and Composition of Multicomponent Alloy

Embodiments include a liquid metal/alloy-assisted wet chemical technique. Methods provided herein for the controllable synthesis alloys can synthesize alloys with increased composition diversity (e.g., above about 20 elements), different morphology (e.g., 0-dimension, 2-dimention, 3-dimension), and crystallinity variations (e.g., single crystal, polycrystalline, mesocrystal, amorphous) under mild conditions (e.g., about room temperature to 80-90° C.).

The methods provided herein include preparing the solution by dissolving the metal salt, such as copper chloride, chloroauric acid, and chloroplatinic acid in deionized water. The methods include subsequently adding some Ga/Ga alloy nanoparticles to the solution as reaction precursors. Because the chemical reaction requires the participation of Ga, limiting the chemical reaction to the liquid-liquid interface according to the methods provided herein can significantly reduce the alloying temperature (e.g., to room temperature to about 80-90° C.) and can significantly reduce the reaction time (e.g., to within about 1 minute) as compared to conventional alloying methods. The methods further include washing and filtration of the precipitates with water for several time, to obtain multicomponent alloy nanoparticles. The morphology and crystallinity can be tuned by controlling the filtration solvent and parameters. In this method, gallium or liquid metal alloy, acting as metal-solvents, effectively blends the metal elements. The resulting high entropy states are kinetically trapped by isothermal solidification instead of rapid cooling. This method is also applicable to other liquid-liquid interfaces, such as the oil-water interface.

Embodiments described herein include a method for the controllable synthesis alloys with increased composition diversity (e.g., above about 20 elements), different morphology (e.g., 0-dimension, 2-dimention, 3-dimension), and crystallinity variations (e.g., single crystal, polycrystalline, mesocrystal, amorphous) under mild conditions (e.g., about room temperature to 80-90° C.). Ga can be completely consumed resulting in Ga-free HEAs. If desired, Ga can be one of the metal elements in the final products.

Methods provided herein can include comprising providing a substrate with a particle comprising gallium or a gallium alloy disposed thereon, and depositing a salt solution including metal precursors on the particle. The salt solution can include HCl. Without wishing to be bound by theory, HCl can remove the native oxide layer on the Ga surface, allowing the liquid gallium to spontaneously break into numerous nanoparticles due to surface tension. The particle can be in a liquid state, and metals of the metal precursors can raise the melting temperature of the particle and cause the particle to solidify. When the particle is not in a liquid state, the methods can further include heating the substrate with the particle disposed thereon to about 25° C. to 80° C. to melt the particle.

The method includes providing gallium or gallium alloy particles in a liquid state; and contacting the gallium or gallium alloy particles with a solution of one or more metal precursors, thereby initiating a reaction to produce an alloy. The solution can include HCl.

In some embodiments, the gallium or gallium alloy particles are loaded on a substrate. The substrate can include a carbon substrate, such as a carbon film substrate.

The particle can be a nanoparticle. The particle can have a size of about 5 nanometers to 1 micron, such as about 5-50 nm, 50-100 nm, 100-200 nm, 200-300 nm, 300-400 nm, 400-500 nm, 500-600 nm, 600-700 nm, 700-800 nm, 800-900 nm, 900-1000 nm, or more than 1000 nm. The metal precursors can be “HₓMCl_{y}, wherein “M” is a metal. In some embodiments, the metals of the metal precursors consist essentially of Pt, Pb, Pd, Au, and Cu. In some embodiments, the metals of the metal precursors include at least three different metals from a group K, V, Cr, Mn, Fc, Co, Ni, Cu, Zn, Ru, Rh, Nd, Cd, In, Sn, Sb, Cs, Nd, Re, Pt, Au, and Pb. The metal precursors can include at least 2, at least 3, at least 4, at least 5, at least 6, at least 7, at least 8, or at least 9 different metals. For example, the metal precursors can include three or more different metals. The metal precursors can include four or more different metals. The metal precursors include five or more different metals. The metal precursors include six or more different metals. The metal precursors can include seven or more different metals. The metal precursors can include eight or more different metals. The metal precursors can include nine or more different metals.

After the particle has solidified, the particle can be a HEA. The HEA can contain any combination of 4, 5, 6, 7, 8, 9, 10, 11, 12, 13, 14, 15, 16, 17, 18, 19, 20, or more metals. For example, after the particle has solidified, the particle (i.e., the HEA particle) can have a composition GaCuPdPtAuPb, GaCuPbZnAuFeCoAl, or AiFeCuPtZnPbInSnPdAuGa. The particle after it has solidified can be HEA containing 4, 5, 6, 7, 8, 9, 10, 11, 12, 13, 14, 15, 16, 17, 18, 19, 20, or more metals. The HEA can be Ga-free.

Further, after the particle has solidified, a morphology of the particle (e.g., HEA particle) can have a high surface to volume ratio (e.g., mesocrystal structure).

The particles or alloys produced by the methods provided herein can comprise composition diversity (e.g., above about 20 elements), different morphology (e.g., 0-dimension, 2-dimention, 3-dimension), and crystallinity variations (e.g., single crystal, polycrystalline, mesocrystal, amorphous). In some embodiments, the method further includes adjusting the reaction temperature, the reaction kinetics, the interface between the gallium or gallium alloy particles and the metal salt solution, or the composition of the gallium or gallium alloy particles or the metal salt solution, to adjust the elemental composition, the size, the crystallinity, or the morphology of the alloy.

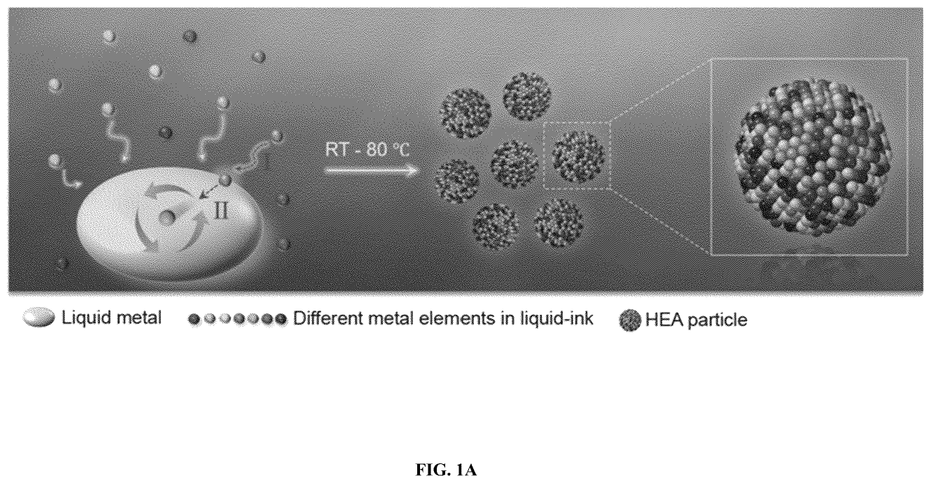

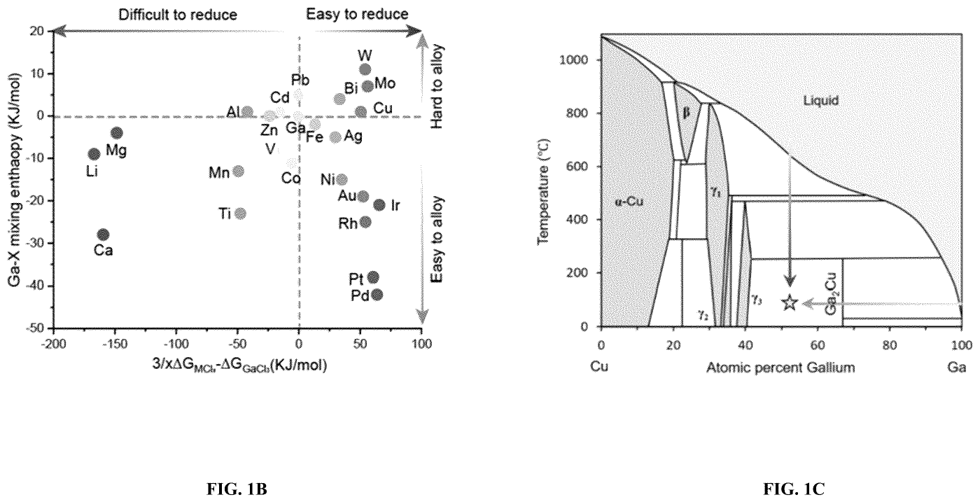

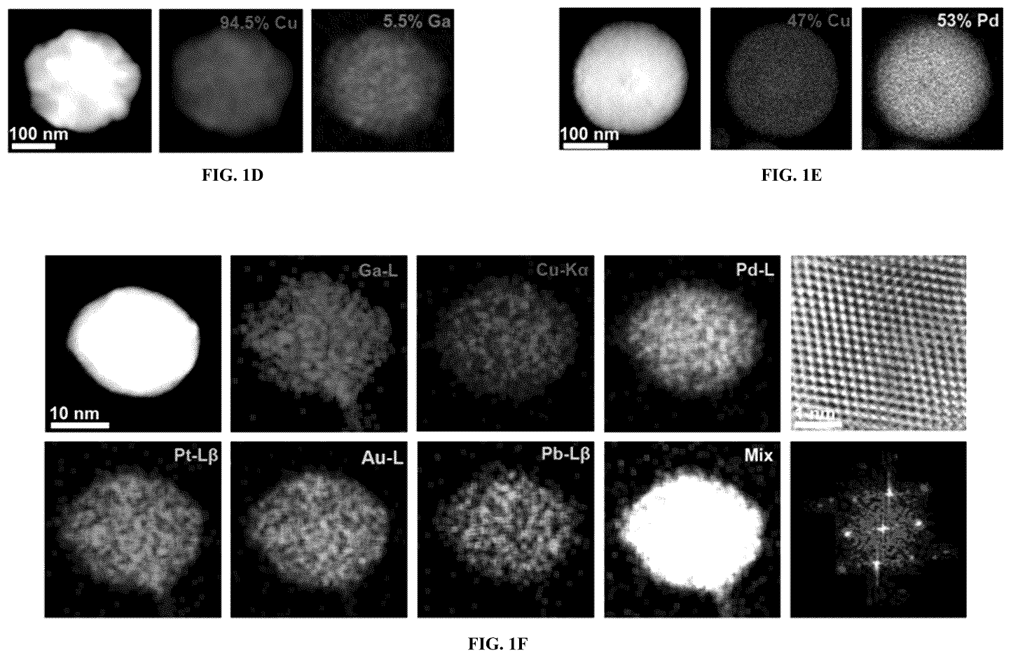

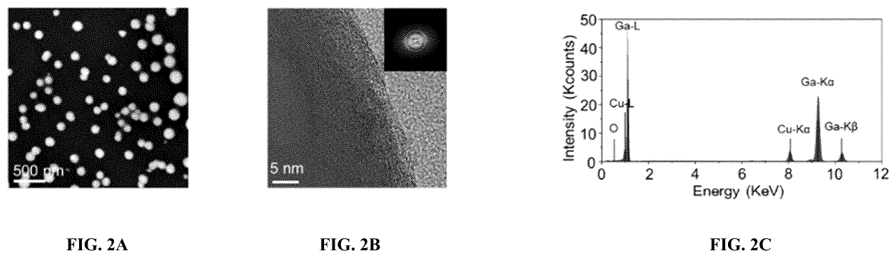

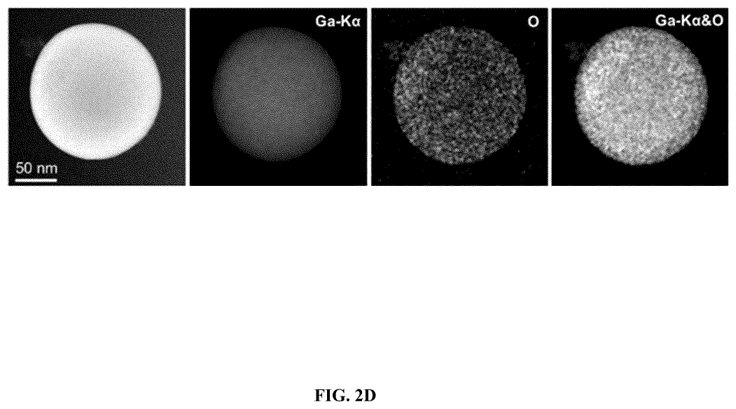

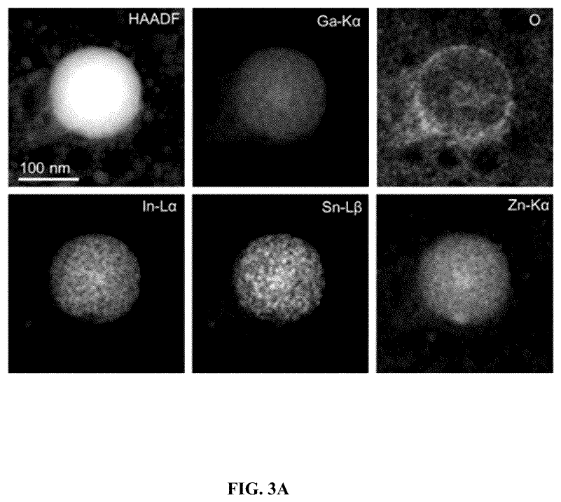

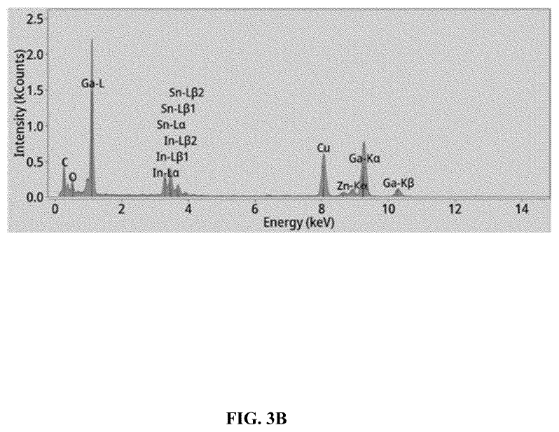

FIG. 1A illustrates the fundamental principle of the isothermal solidification strategy for synthesis of HEAs, with liquid metals (e.g., Ga or Ga-based alloys) employed as the metal solvents and the metal ion reduction reaction taking place at the interfaces of liquid metal with an acidic salt solution (pH 1.0). TEM characterization of Ga nanoparticles is shown in FIG. 2A-2D, and EDS characterization of a GISZ nanoparticle are shown in FIGS. 3A-3B.

The formation of HEAs involves two steps: (I) the metal ions are reduced by Ga at the interfaces between the liquid metal and the salt solution; (II) incorporation of metal atoms from step I into the liquid metal and isothermal solidification to form HEAs, i.e., the resulting foreign metal atoms readily dissolve into the liquid metal while the liquid Ga dissolves into the solution (Ga→Ga³⁺), which drives the liquid metal alloy into a supercooled state with the composition becoming less rich in Ga. The isothermal solidification leads to HEAs formation. Since Ga-based liquid metals interact strongly with other metal elements, they are ideal solvents for the dynamic mixing of metal elements. At the interfaces of the liquid metal with the aqueous salt solution, the reduction reactions occur:

$$Ga ( l ) + \frac{3}{x} {M Cl}_{x} ( aq ) \to {GaCl}_{3} ( aq ) + \frac{3}{x} M ( s ) ,$$

where M denotes the foreign metal and x represents the valence states of the foreign metal. The fast incorporation of foreign metal atoms from the reduction reaction into the liquid metal solvent may continuously refresh the reduction reaction. Moreover, the concurrent consumption of the Ga in liquid metal alloys further accelerates the increase of the liquid metal solute concentration, which leads to oversaturation or a supercooled state.

FIG. 1B depicts thermodynamically informed design map. The reducibility (3/xΔGMClx-ΔGGaCl₃) of metals is considered to assess the feasibility of the reduction reaction in Step (I) described above. Metals corresponding to ions positioned to the right of the dashed line can be spontaneously reduced by Ga at RT. The mixing enthalpy between Ga and other metals serves as an indicator of alloy miscibility in Step (II) described above. Only the mixing enthalpy of binary alloys is listed in FIG. 1B, where the values of binary liquid alloys were calculated using the Miedema model at an equi-atomic composition. For multi-element alloys, the miscibility is governed by the mixing entropy of the entire element system.

For HEAs synthesis using Ga liquid metal, the reducibility and miscibility of metals are governed by two parameters (FIG. 1B): the reducibility of metal ions by Ga is estimated by

$$\frac{3}{x} Δ {G}_{{MClx}^{-}} Δ {G}_{Ga} {Cl}_{3} ,$$

assessing the feasibility of the reduction reaction in Step I; and miscibility of metals with Ga is represented by the mixing enthalpy (ΔHₘᵢₓ), describing the readiness of the foreign metal to alloy with Ga in Step II. The enthalpies of mixing used for this analysis were computed using Miedema's model for 1:1 molar mixtures of various Ga-X pairs in the solid state at RT²². Because the product composition varies during isothermal solidification and the mixing process occurs in the liquid state, we treat these: ΔHₘᵢₓ values as a qualitative criterion for the formation of a solid solution in Step II, based on phase formation rules. According to these criteria, elements positioned in the first and fourth quadrants of FIG. 1B correspond to those that can undergo spontaneous reduction from their aqueous metal chloride solutions. Moreover, elements positioned near the left of the vertical boundary (e.g., Cd, V, Co) can also undertake reduction upon thermal heating.

The innovative liquid-liquid interface engineering method, with unique mixing and solidification mechanisms, offers unparalleled control over the crystallinity and morphology of high entropy alloys. Compared to high-temperature methods (e.g., the Carbothermal shock and the high-temperature anneal methods), the methods provided herein operate at a lower reaction temperature, even room temperature. The morphology and crystallinity of the HEA nanomaterials are diverse and can be controlled by adjusting the reaction parameters. The difference of the methods provided herein, e.g., the isothermal solidification HEAs synthesis from the previously available methods is summarized in Table 1 and further described as follows:

The previously available liquid metal-assisted HEA synthesis method (e.g., Cao et al., Nature 2023, 619, 73-77), uses liquid metal as a reaction media to reduce mixing enthalpy (focused open questions). In terms of mechanism, (1) the synthesis process is a stable thermodynamic process and the synthesized HEAs have Ga elements. (2) The reduction reaction is not limited at the interface between salt solution and liquid Ga. Indeed, the previous method also involves two steps: reduction of the metal salt and dissolution of the metal into Ga. But the metal salts are thermally decomposed or reduced by H₂ into metal elements. The reduction of metal salts is not limited to the surface of Ga metal; instead, metal salts can also be reduced and nucleate at other locations, growing into metal particles. In contrast, according to the methods provided herein, the reduction of metal salt is limited to the liquid-liquid interface, i.e., the surface of Ga or Ga alloy. (3) The alloying speed is relatively slow and don't need kinetic trap of high-mixing states. Under thermal conditions, the liquid Ga metal undergoes fusion and fission, dissolving other metals into the liquid metal to form HEAs. The process usually requires 30 to 120 minutes and is slower compared to the methods provided herein. Further, the samples are naturally cooled to room temperature at a relatively low cooling rate, unlike the HEA formation process provided herein that involves kinetic trapping. (4) The formed HEAs always exist in particle form and contain Ga elements. Since the thermodynamically stable alloying process relies on Ga as a mediator to achieve a negative mixing enthalpy, the resulting high entropy alloy must contain Ga and typically form as particles. Otherwise, the concept of Ga facilitating negative mixing enthalpy with other metals would not hold. In contrast, Ga can be removed from the HEA according to the methods provided herein.

The previously available galvanic replace reaction method (e.g., Gan et al., Chem. Mater. 2024, 36, 3042) uses polydopamine (PDA) shells to control the nucleation and growth of reduced metal nanocrystals and use Ga core as reducing agent in the galvanic reaction. In terms of mechanism, (1) the galvanic replacement reaction method involves the galvanic replace process, where metal and multi-metallic alloy formation occurs through co-reduction on the PDA shell. In this process, unlike the methods provided herein, Ga serves solely as a reducing agent, without involving the rapid elemental exchange in the liquid alloy or the kinetic trapping of the high entropy state. (2) the reduction reaction is confined to the PDA shell to facilitate the nucleation and growth of metal particles on the surface. The reacting ions are negatively charged metal ions (e.g., AuCl₄⁻, PtCl₄2−, PdCl₄2−) rather than positively charged metal ions. In contrast, in the methods provided herein, the reduction reaction is limited to the liquid-liquid interface to accelerate elemental exchange within the liquid alloy and achieve kinetic trapping of high entropy states.

In contrast, in the methods provided herein, by limiting the reduce reaction at the Liquid Ga-salt solution interface, the composition change in the liquid metal alloy can be accelerated at constant temperatures, thus kinetically trapping the high entropy alloy state. The methods provided herein can involve an isothermal solidification strategy that rapid changes of metal alloys composition lead to the formation of HEAs without modulating the temperature. Regarding the mechanism, first, the alloying process provided herein involves kinetic trapping, unlike the previously available methods. The kinetic trapping is achieved through rapid compositional changes rather than rapid cooling. Secondly, the methods provided herein can involve a unique liquid-liquid interface reaction. In the methods provided herein, Ga reduces the metal salt, while the resulting foreign metal atoms are simultaneously dissolved into Ga. This dynamic exchange plays a crucial role in rapidly altering the composition of the liquid metal and facilitating rapid solidification. Additionally, unlike the previously available methods, the generation of H₂ during the reaction, which not only facilitates stirring and enhances the mixing of metal elements but also influences the structure of high entropy alloys, leading to the formation of complex structures such as porous and hollow high entropy alloys. Since our reaction consumes Ga and generates gas, we can regulate reaction parameters to control the elemental exchange rate at the liquid-liquid interface. This allows us to tailor the shape, crystallinity, and porosity of the resulting high entropy alloys, with or without Ga metal.

In contrast to the dropwise synthesis method (e.g., Liu, Y.-H. et al., Sci. Adv. 2023, 9, eadf9931), this approach offers a shorter reaction time, lower reaction temperature, and the ability to introduce immiscible elements by controlling the thermal dynamics, resulting in a more diverse morphology of HEAs with customizable crystallinity. Compared to the Ga liquid metal-assisted method (e.g., Cao et al., Nature 2023, 619, 73-77), the methods provided herein offer various controlled morphology and crystallinity, along with shorter reaction times and milder reaction temperatures. Unlike other high-energy input methods (e.g., electro-shock method (e.g., Glasscott, M. W. et al. Nat. Commun. 2019, 10, 2650) and laser scanning ablation method (e.g., Wang, B. et al. Nat. Synth. 2022, 1, 138-146)), the methods provided herein does not require complex equipment, allows for the incorporation of a wider variety of metallic elements, and, importantly, can synthesize HEAs with desired crystallinity and complex morphologies as needed. Therefore, the liquid-liquid interface engineering method is an efficient and controllable approach for preparing diverse morphologies and crystallinities of HEA nanomaterials, possessing great potential for industrial applications (see Table 1).

In summary, the methods provided herein differ from the presently available technology in terms of the underlying mechanism and the details of alloying, enabling control of the HEAs such as crystallinity and morphology.

TABLE 1
Comparison between different HEA synthesis methods

| | Energy | | | | | |
|---|---|---|---|---|---|---|
| Methods | conditions | Composition | | Crystallinity | Morphology | Environment |
| Liquid-liquid | RT-353K | 20 | elements | Single-crystal, | 0-D (solid, porous, | Metal salt solution |
| interface engineering | | | | mesocrystal, | hollow, core-shell | |
| (present disclosure) | | | | polycrystal, | spherical); flower- | |
| | | | | amorphous | like, dendrite, | |
| | | | | (Controllable) | nanosheets; network- | |
| | | | | | like, hierarchical | |
| | | | | | structure, chiral | |
| | | | | | structure | |
| | | | | | (Controllable) | |
| Carbothermal shock | ~2000K | 8 | elements | Single-crystal | Nearly spherical | Air environment |
| High T anneal | 873-1373K | 6 | elements | Single-crystal | Nearly spherical | Metal salt solution |
| Dropwise | 453K | 5 | elements | Single-crystal | Dendrite; core-shell, | Metal salt solution |
| | | | | | irregular shapes | |
| Liquid Ga-assistant | 923K | 17 | elements | Single-crystal | Nearly spherical | 50-sccm Ar and |
| | | | | | | 300-sccm H₂ |
| | | | | | | atmosphere |
| Electro-shock | −1.5 or | 8 | elements | Amorphous | Nearly spherical and | Metal salt solution |
| | −0.4 Volt | | | | irregular shapes | |
| Laser scanning | 1064 Fiber | 9 | elements | Single-crystal | Nearly spherical | Metal salt solution |
| ablation | laser | | | | | |

### B. High Entropy Nanomaterials of the Invention

By controlling the synthesis parameters according to the methods provided herein, multicomponent nanoparticles with different sizes (about 5 nm to 1 μm), crystallinity (single crystal, mesocrystal, polycrystalline, amorphous) and morphology (sphere, nanosheets and hierarchical structures) can be fabricated.

With respect to elemental composition, many novel high entropy alloy nanoparticles, including GaCuPdPtAuPb, GaCuPbZnAuFeCoAl, and AiFeCuPtZnPbInSnPdAuGa, are provided herein. In some embodiments, HLAs provided herein are Ga free. HLAs with any combination of elements can be synthesized using the methods provided herein.

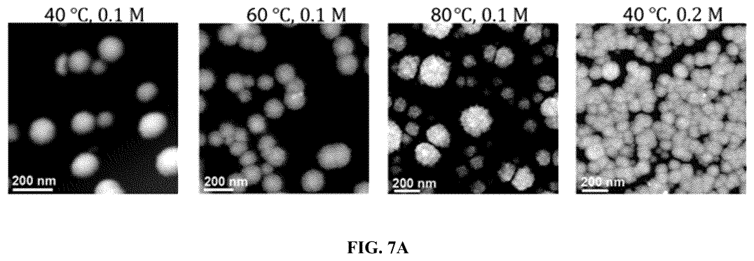

With respect to crystallinity, novel mesocrystal HEA is provided. The example features of the mesocrystalline HEA are depicted in, for example, FIGS. 7C, 9A-9G, and 10A-10E. The crystallinity of HEAs with any combination of elements can be adjusted as needed.

With respect to morphology, provided herein are HFAs with new hierarchical structures, such as grape-bunch structure, core-shell structure and multiple shell structure. HFAs having novel elemental composition, crystallinity, and/or hierarchical structures provided herein can be produced using the methods provided herein.

The diversity of the HEAs provided herein, such as those produced using the methods provided herein, gives them unique properties for use in catalysis, electronics, thermoelectricity, mechanics, and other fields. In situ liquid phase transmission electron microscopy (TEM) studies and theoretical analysis reveals the liquid metal motion enhanced elemental mixing and the solidification process with fluctuating nucleation dynamics, as further described below. The isothermal solidification marks a powerful strategy for HEA synthesis through an unexplored pathway of kinetically trapping the high entropy states.

The formation process of HEA-NPs including H₂ nucleation, metal incorporation, mixing, and crystallization can be observed in situ as follows. In the initial stages of the reaction, hydrogen generation propels the movement of liquid HEA, effectively acting as a stirring bar. This gas-assisted rapid string mechanism for metal alloying at the nanoscale is distinct compared with previous reported alloying methods. The temperature is about 60° C. throughout the alloying process, which eliminates a sudden temperature drop as the cause of instantaneous crystallization. Instead, it can be attributed to an elevation in the melting point induced by alterations in the composition of liquid alloy. This marks the instance of employing composition changes to kinetically trap the high entropy state throughout the alloying process.

Compared with conventional HFA formation technologies, advantages of embodiments described herein include the following:

HEAs provided herein are obtained through a facile method. The synthesis process does not require complicated equipment and can be completed within about 1 minute at low temperature (about room temperature to 80° C.). This is in contrast to the known HEAs synthesis methods depend on high temperature or high energy. The mild reaction environment for producing HEAs has advantages.

HFAs provided herein have diverse morphology. Some HEAs with previously unachievable morphologies that exhibit superior catalytic properties can be obtained by the methods provided herein. These morphologies provide more abundant reaction sites, which can enhance the efficiency of processes such as CO₂ electroreduction, hydrogen evolution reaction, and ammonia oxidation.

HFAs provided herein include mesocrystal structured HEAs. Mesocrystal structure combines the properties of single crystals and nanoparticles, resulting in enhanced optical, electronic, magnetic, or catalytic properties compared to conventional nanoparticles or bulk materials. Mesocrystals typically have a high surface area due to their porous structure, which makes them suitable for applications requiring high surface-to-volume ratios, such as catalysis and sensing. Their ordered structure provides better stability against aggregation or dissolution compared to randomly assembled nanoparticles, making them more robust in various environments.

HFAs provided herein include high entropy metal glasses. The novel high entropy metal glasses possess high strength and hardness, making them suitable for structural applications where strength and durability are needed. They also exhibit a high elastic limit, meaning they can withstand large deformations without undergoing permanent damage. This property is beneficial for applications requiring resilience to mechanical stress or impact. They have excellent corrosion resistance due to their homogeneous and amorphous structure, making them ideal for applications in aggressive environments.

### C. Homogeneous Nucleation Rate and Supercooling

From classical nucleation theory, the nucleation rate can be related to the degree of supercooling (ΔT=T−T_{L}). The nucleation rate is given by:

$$J = K exp [ \frac{- Δ {G}^{*}}{{k}_{B} T} ]$$

Where J is the nucleation rate in units of

$$\frac{1}{s \cdot ml} ,$$

K is a pre-exponential factor related to atomic density, number of nucleus surface atoms, and vibrational properties of the constituent atoms. ΔG* is the energy barrier associated with producing a nucleus that will spontaneously grow. This value is given by:

$$Δ {G}^{*} = \frac{16 {πγ}^{3}}{3 Δ {G}_{V}^{2}}$$

Where γ is the surface energy of the nucleus and ΔG_{V} is the volume normalized energy change associated with converting liquid to solid. Specifically, this value is:

$$Δ {G}_{V} = \frac{1}{{V}_{m}} ( {G}_{s}^{∘} - {G}_{l}^{∘} ) = \frac{1}{{V}_{m}} [ {H}_{s}^{∘} - {TS}_{s}^{∘} - {H}_{l}^{∘} + {TS}_{l}^{∘} ]$$

$$Δ {G}_{V} = \frac{1}{{V}_{m}} [ T ( {S}_{l}^{∘} - {S}_{s}^{∘} ) - ( {H}_{l}^{∘} - {H}_{s}^{∘} ) ]$$

We also observe that at T=T_{L}:

$${G}_{l}^{∘} ( {T}_{L} ) = {G}_{s}^{∘} ( {T}_{L} )$$

Thus,

$${H}_{l}^{∘} - {T}_{L} {S}_{l}^{∘} = {H}_{s}^{∘} - {T}_{L} {S}_{s}^{∘}$$

$$and ,$$

$${H}_{l}^{∘} - {H}_{s}^{∘} = {T}_{L} ( {S}_{l}^{∘} - {S}_{s}^{∘} )$$

Using this expression for

$${H}_{l}^{o} - {H}_{s}^{o} ,$$

the change in Gibb's free energy associated with the phase transformation becomes:

$$Δ {G}_{V} = \frac{1}{{V}_{m}} [ T ( {S}_{l}^{∘} - {S}_{s}^{∘} ) - {T}_{L} ( {S}_{l}^{∘} - {S}_{s}^{∘} ) ) ]$$

$$Δ {G}_{V} = \frac{1}{{V}_{m}} ( T - {T}_{L} ) ( {S}_{l}^{∘} - {S}_{s}^{∘} )$$

Then, we can define the volumetric entropy change:

$$Δ {S}_{V} = \frac{{S}_{s}^{∘} - {S}_{l}^{∘}}{{V}_{M}}$$

Such that:

$$Δ {G}_{V} = - Δ {S}_{V} Δ T$$

Because ΔS_{V} is negative (entropy of the liquid phase is higher than entropy of the solid phase), ΔG_{V} is only negative if ΔT is negative, since ΔT=T−T_{L}, a driving force for homogeneous nucleation is only present if T<T_{L}, that is, if there is some degree of supercooling, and the size of this driving force increases with degree of supercooling (ΔT).

The energy barrier can be expressed as a function of supercooling (ΔT) as well:

$$Δ {G}^{*} = \frac{16 {πγ}^{3}}{3 Δ {G}_{V}^{2}} = \frac{16 {πγ}^{3}}{3 Δ {{S}_{V}^{2} ( Δ T )}^{2}}$$

Thus, as the temperature decreases, |T−T_{L}| and (ΔT)² increase, and the energy barrier for nucleation, ΔG*, decreases. In turn the rate of nucleation increases as temperature drops below the liquidus temperature according to the following expression.

$$J = K exp [ \frac{- Δ {G}^{*}}{{k}_{B} T} ] = K exp [ \frac{- 16 {πγ}^{3}}{3 {k}_{B} T Δ {{S}_{V}^{2} ( Δ T )}^{2}} ]$$

Due to competition between the T and (ΔT)² terms, the nucleation rate reaches a maximum at an intermediate temperature between T=0 and T=T_{L}. This is shown schematically in FIG. 4: the particular shape of the curve (including the position of the border between Regions 1 and 2) is determined by factors such as the nucleation pre factor, surface energies, and entropy differences between the solid and liquid phases.

During the HEA syntheses provided herein, an increasing solidification rate can be observed when increasing the synthesis temperature. Due to the likely extreme degree of supercooling in this system, this increase of solidification rate with temperature may indicate that this synthesis procedure occurs in Region 1 of FIG. 4, i.e. at a degree of supercooling where increasing temperature increases nucleation rate.

### EXAMPLES

### Example 1. Isothermal Solidification Strategy

This Example provides an embodiments of the isothermal solidification strategy using the Ga—Cu binary alloy, which features a low solubility of Cu in liquid Cu—Ga alloy at temperatures below 100° C. (less than 3%).

FIG. 1C depicts phase diagram of a representative Cu—Ga binary alloy, demonstrating two solidification routes. The widely used rapid cooling solidification of the high temperature Ga—Cu liquid alloys leads to kinetic trapping of the alloy mixture, as highlighted by the red arrow (FIG. 1C). However, as an alternative route highlighted by the blue arrow, drastically increasing the miscibility of Cu in liquid Ga creates an oversaturated liquid alloy (a supercooled liquid state) and the subsequent isothermal solidification yields a high-Cu-content alloy.

Binary Cu—Ga alloys were successfully synthesized using the isothermal solidification method at a constant temperature of 60° C. Energy-dispersive X-ray spectroscopy (EDS) analysis (FIG. 1D) reveals that the Cu content reached up to 95%, with the two elements homogeneously distributed. In addition, the isothermal solidification may also generate Ga-free alloys, e.g., Cu—Pd alloys (FIG. 1E). The isothermal solidification can effectively synthesize HEAs with arbitrary elemental compositions (FIG. 1F). Example molar ratios of elements in the GaCuPdPtAuPb HEA corresponding to FIG. 1F is described in Table 2.

TABLE 2
Example molar ratios of elements in the
GaCuPdPtAuPb HEA corresponding to FIG. 1F

| HEA | Ga | Cu | Pd | Pt | Au | Pb |
|---|---|---|---|---|---|---|
| Single crystal | 8.3% | 17.2% | 33.2% | 1.9% | 31.3% | 8.1% |
| GaCuPdPtAuPb | | | | | | |

### Example 2. Isothermal Solidification Mechanisms Revealed by Liquid-Cell TEM

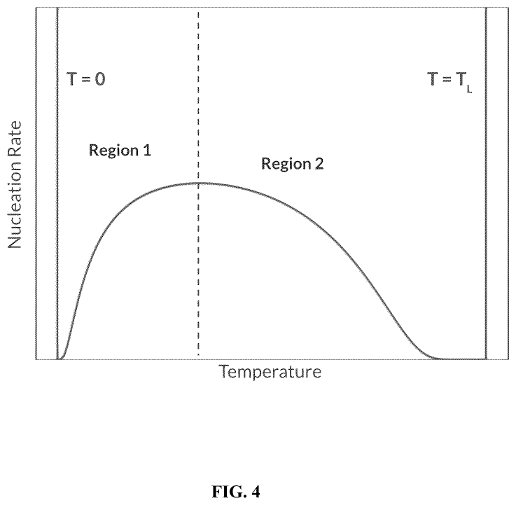

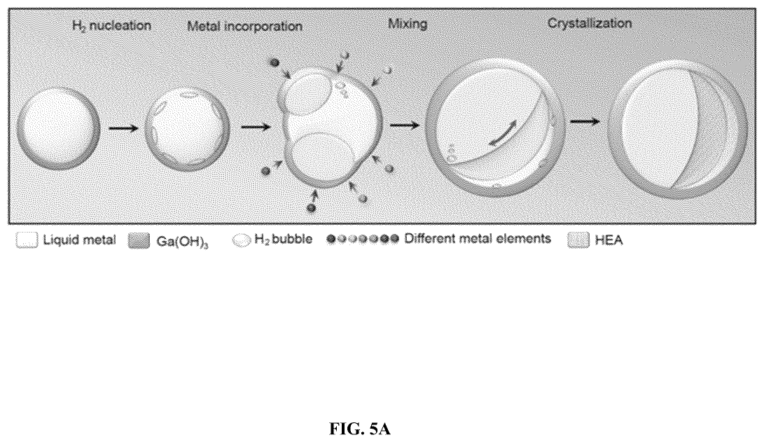

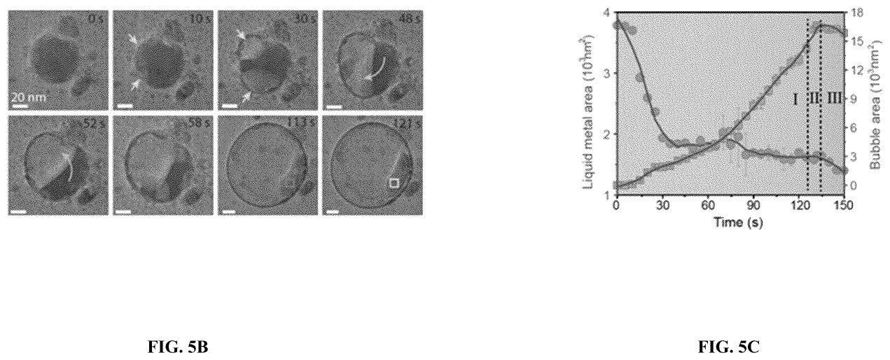

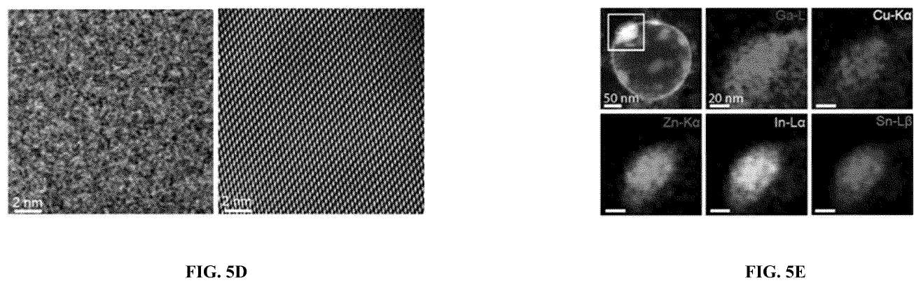

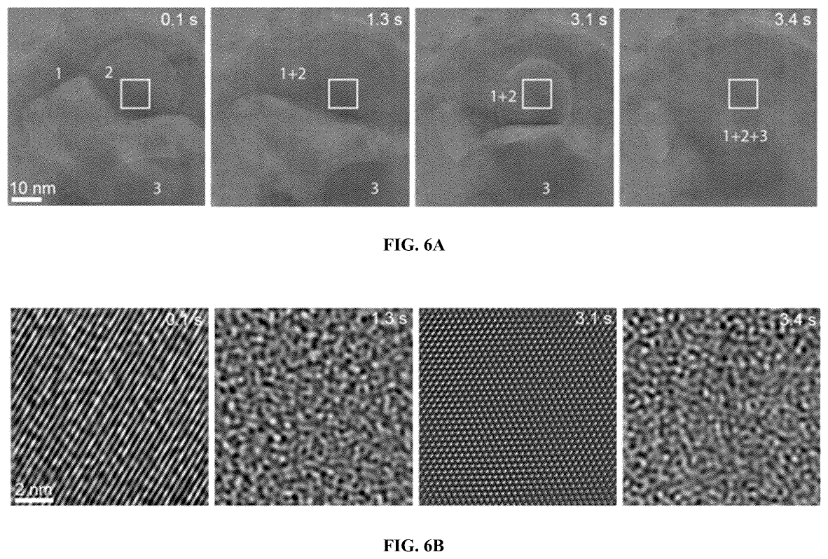

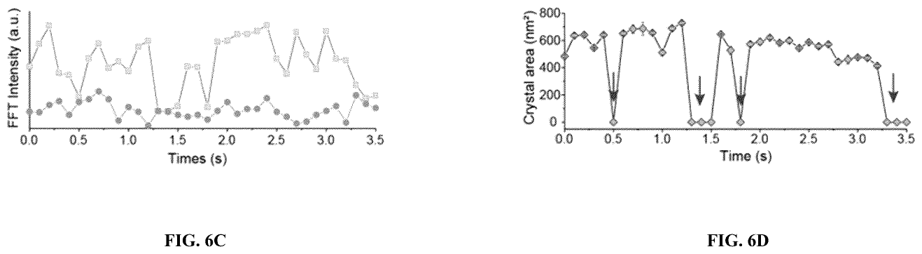

To uncover the underlying mechanisms of isothermal solidification for HEAs synthesis, direct observation of the alloying process at the atomic level using advanced liquid cell TEM was conducted (FIGS. 5A-5E, 6A-6D). In a simplified model system, we introduce Cu as a single additional element into the host liquid metal of Ga-based alloy (e.g., GISZ, composed of Ga, In, Sn, Zn) to form single-crystal HEA-NPs, specified as GaSnInZnCu.

The dynamic evolution of the HEA-NPs formation was tracked. At the initial stage (FIG. 5A), the liquid metal nanoparticle is encased in a Ga₂O₃ shell (FIG. 5A), which transforms into GaOOH through hydrolysis reaction in the aqueous solution. Ga from the liquid metal reacts with cations in the solution (e.g., H⁺ and Cu²⁺), generating H₂ gas and Cu metal atoms. The formation of H₂ is marked by the appearance of nanobubbles at the GaOOH-liquid metal interface (indicated by yellow arrows in FIG. 5B). The generated Cu atoms are incorporated into the liquid metal, as evidenced by EDS characterization of the final HEA (FIG. 5E). Small gas bubbles coalesce into a larger bubble while the liquid metal circulates along the inner shell (indicated by indigo arrows) (30-58 s). This hydrogen gas-assisted stirring greatly enhances the metal element mixing. As the reaction proceeds, gas bubbles continue to evolve, driving the bubble expansion (FIGS. 5A-5C). Simultaneously, Ga is gradually depleted from the liquid metal while Cu atoms continuously join in (FIG. 5C). After 121 seconds, the fluidity of the liquid metal alloy quickly decreases, signaling its transition to a solid state (FIG. 5D). The temperature remains at 60° C. throughout the alloying and solidification processes, indicating that the isothermal solidification. During the final crystallization, the gas bubble briefly expands before contracting and the liquid metal undergoes slight reshaping before it is finally stabilized (FIG. 5C). High-resolution TEM (HRTEM) imaging (FIG. 5D) and EDS characterization (FIG. 5E) confirm the single-crystal structure and homogeneous distribution of metal elements within the resulting HEA-NPs. Therefore, the dynamic evolution of the HEA-NPs formation can be summarized as hydrogen gas bubble assisted mixing followed by isothermal solidification of the liquid alloy and reshaping during final crystallization.

FIG. 5C reveals that the isothermal solidification of the liquid alloy takes several seconds, which is contradictory to the common notion that the supercooled liquid alloy would undergo fast solidification (Turnbull, D., J. Chem. Phys. 1952, 20, 411-424). To explore this further, atomic-resolution observation of the dynamic isothermal solidification was conducted. As shown in FIGS. 6A-6D, oscillatory solidification of the liquid alloy was found. The H₂-gas driven dynamics result in continuous splitting and reforming of the metal alloy domains. For instance, as shown in FIGS. 6A-6B, Domain 2 with an initial crystalline structure converts to an amorphous liquid-like structure after it rapidly merges with Domain 1. During the progression, crystallization occurs repeatedly, and then it breaks down into an amorphous structure upon interaction with new domains. The oscillatory nucleation and disruption are illustrated in FIGS. 6C-6D by measuring the changes of crystal diffraction spot intensities and the projected area of the crystalline domains with time. Notably, phase transitions between crystalline and amorphous states may occur within a single observation frame (0.1 s) (FIG. 6D. This implies that the solidification is fast, which helps effectively trap the high entropy state of liquid metal.

Theoretical analysis of nucleation and solidification in this scenario supports our observation. According to classical nucleation theory, nucleation rate first increases with degree of supercooling, but eventually begins to decrease due to the retarding effect of a low absolute temperature on the rate of appearance of critically sized nuclei. This trend is captured by Eq. 1, in which ΔT is the degree of supercooling, T is the absolute temperature, ΔS_{V} is the difference in entropy between the solid and liquid phases, γ is the interfacial energy between the solid and liquid phases and K is a geometrical prefactor. Since the method provided herein takes place at low temperatures (RT-80° C.), the isothermal solidification process may occur in this regime of extreme supercooling and a depressed nucleation rate due to the low synthesis temperature may contribute a delay to the solidification process, as described above.

$$J = K exp [ \frac{- 16 {πγ}^{3}}{3 {k}_{B} T Δ {{S}_{V}^{2} ( Δ T )}^{2}} ] ] \qquad ( Eq . 1 )$$

When solid nuclei do appear, their growth may be inhibited by the mixing motion of hydrogen bubbles produced by the reduction of H⁺, which destroys growing product nuclei and further delays solidification. This is consistent with the in situ observation that the H₂-gas assisted stirring of the liquid repeatedly disrupts the crystallization. Finally, at the beginning of the synthesis process, no Ga is present in the aqueous phase and as a result, there exists a favorable thermodynamic driving force for Ga to dissolve into it. This dissolution driving force, in combination with the driving force for the reduction reaction, drives the quick incorporation of foreign metal atoms into the product nanoparticle and enables the fast compositional changes necessary to kinetically trap high entropy states during the isothermal solidification process.

To eliminate the effects of the electron beam on conclusions drawn from the in situ experiments, two systematic control experiments were conducted, including (1) in situ experiments without heating and (2) ex situ experiments without an electron beam. The first control experiment without heating showed no alloying phenomena occurred without heating the sample. Therefore, the electron beam can be ruled out as the cause of the observed alloying process.

The second control experiment without the electron beam also excluded the influence of the electron beam on the alloying process. For all ex situ processes of HEA alloying, the HEA state were reached after the reaction with no electron beam involved. Therefore, the formation of HEA-NPs observed under controlled electron beam conditions accurately reflects the actual situation of ex situ synthesis.

### Example 3. Controllable Synthesis of HEAs With Varying Crystallinity and Morphology

Utilizing the isothermal solidification strategy, we adjusted the reaction temperature and metal salt concentration to control the solidification rates. This allowed precise regulation of the structure and crystallinity of the resulting HEA (FIGS. 7A-7E). The study specifically targets on a system consisting of thermodynamically immiscible elements: Ga, Pt, Pd, Au, Cu, and Pb. The mixing enthalpy among these metal elements are listed in Table 1.

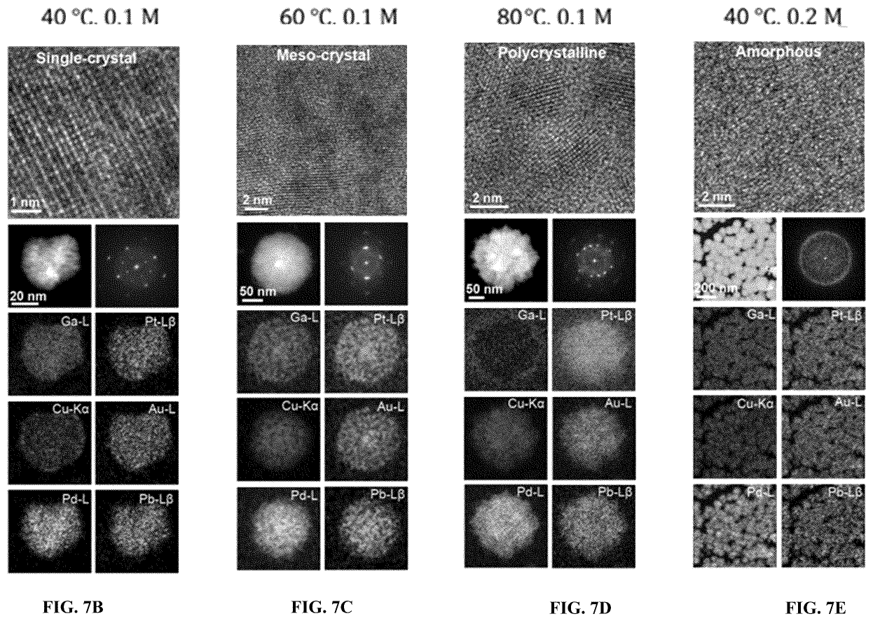

Due to the differences in atomic size, electronegativity, and lattice parameters among these metals, phase separation often occurs during thermodynamic processing (FIG. 8, Table 2), which makes this alloy an ideal candidate for exploring synthesis under non-equilibrium conditions.

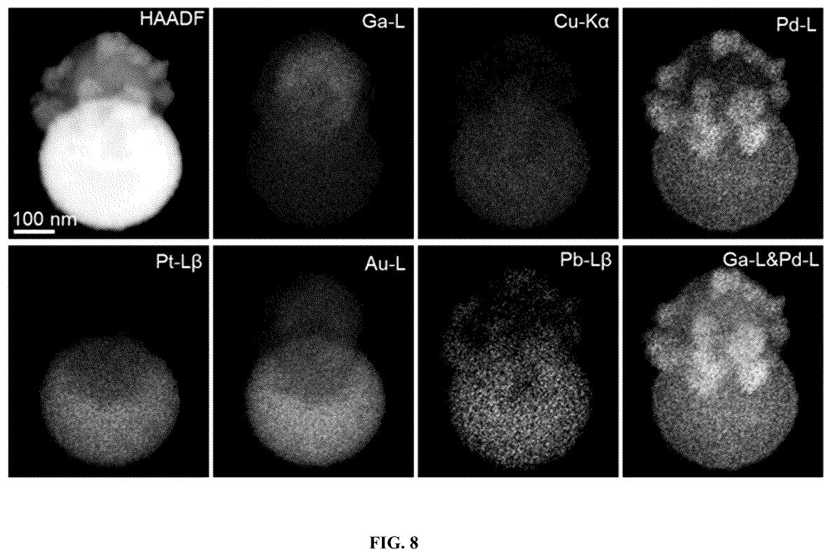

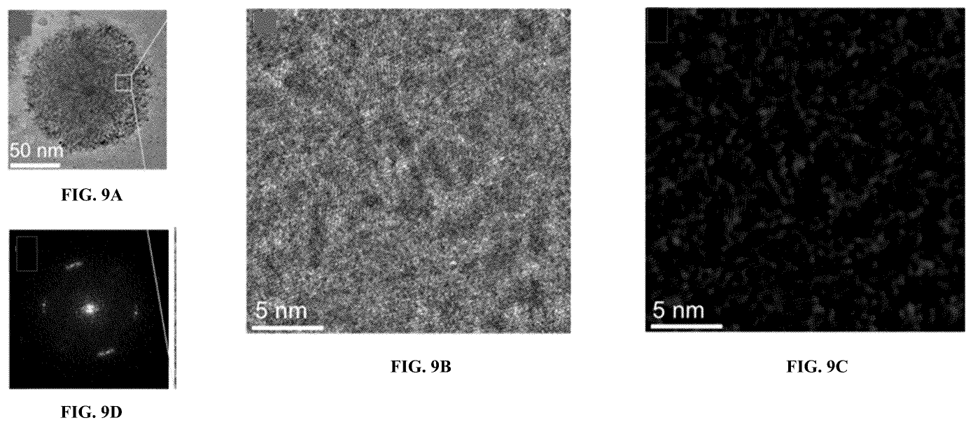

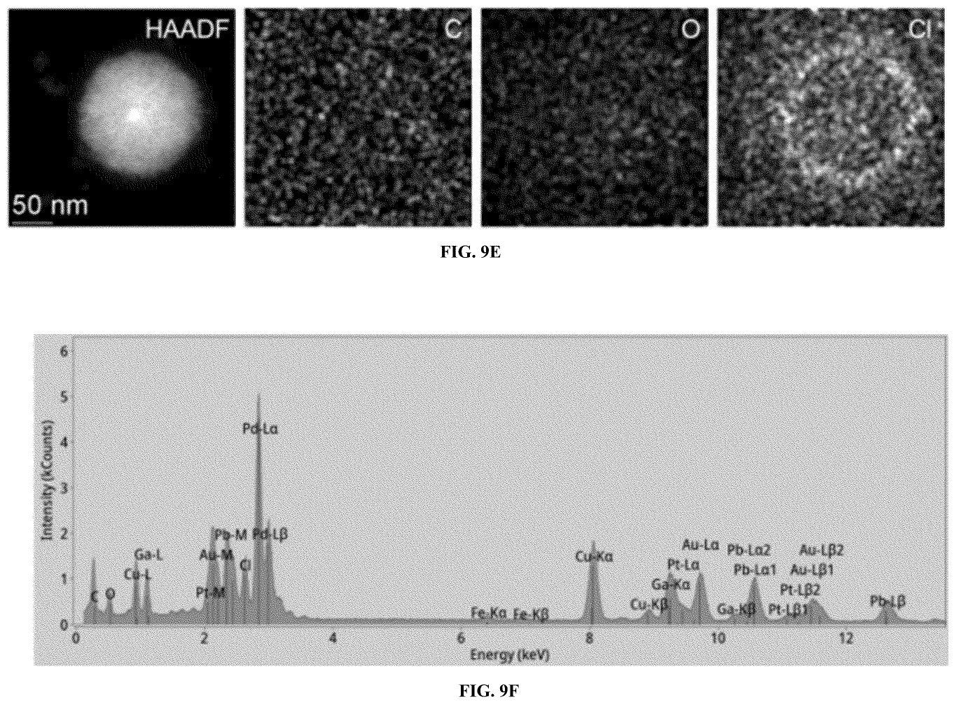

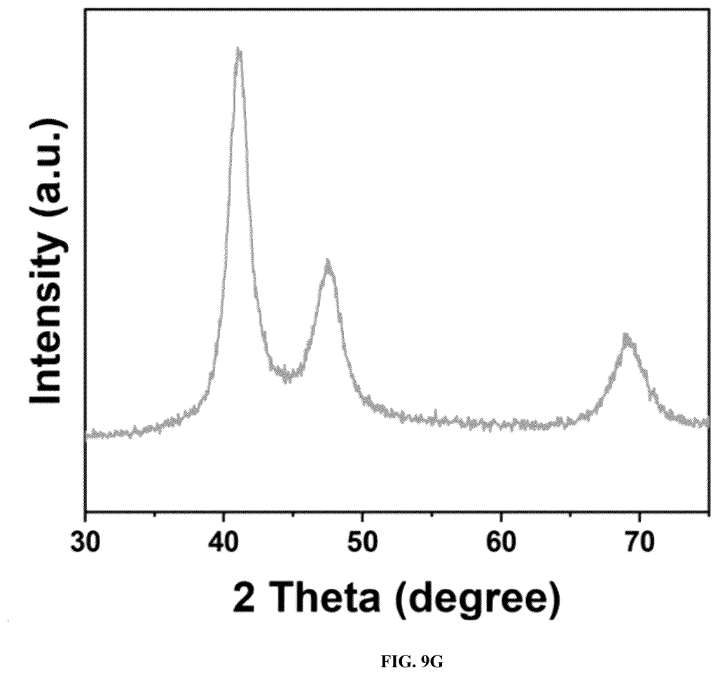

At 40° C., metal atoms, produced through a gentle reaction, dissolved into the liquid Ga and mixed thoroughly. As the melting point of the liquid alloy (which varies with its elemental composition) rises above 40° C., the alloy solidified from a supercooled state, forming a uniform solid solution with high crystallinity (FIGS. 7A-7B). At higher temperatures (e.g., 60° C.), the solidification rate increased, the time required to achieve perfect crystallization is not sufficient. reducing the available time for perfect crystallization. Consequently, the nanoparticles exhibit a mesocrystalline structure with a distinctive architecture (FIGS. 7C, 9A-9D): large porous spherical particles (100-300 nm) composed of numerous smaller nanoclusters (2-5 nm). In general, the solidification of liquid alloys often results in volume shrinkage, which can contribute to the formation of a porous structure. Additionally, the higher rate of gas generation can cause gas to become trapped within the alloy, further promoting the porosity. Notably, within this mesocrystalline matrix, local lattice distortions and bending were observed (FIGS. 9A-9D), likely due to the stress from gas generation and the high surface tension of the liquid metal prior to solidification. By further increasing the temperature to 80° C., polycrystalline HEA-NPs with a flower-like morphology are produced (FIG. 7D). EDS mapping reveals that nearly all the Ga is consumed, leaving the remaining five elements evenly distributed throughout the particles. The complete consumption of Ga may stem from an accelerated solidification rate. The polycrystalline phase and flower-like morphology may arise from dynamic heterogeneities and the mobility asymmetry of supercooled liquids. The observed crystallinity variations with temperature are consistent with theoretical predictions shown in FIG. 4.

Interestingly, amorphous HEA was found by doubling the concentration of metal precursor solution at 40° C. while keeping all other parameters constant (FIG. 7E). This adjustment boosts the influx of foreign metals at the liquid-liquid interface but preserving their diffusion rate. Consequently, foreign atoms entering liquid metal and accumulate rapidly, thus promoting solidification. In this case, spherical HEA-NPs are obtained with amorphous phase. The solid spherical shape indicates that no gas entered the particle during the reaction at 40° C., akin to the case in FIG. 7B. The uniform distribution of metal elements indicates that the metal atoms have diffused sufficiently, result in thorough mixing. Hence, we deduce that the amorphous structure arises from the swift dissolution of foreign metal atoms, leading to deep undercooling of the liquid alloy, followed by the prompt solidification of the liquid alloy. As foreign atoms enter, the melting point of the liquid alloy quickly surpasses its temperature. Nevertheless, in the absence of crystal nucleation, the liquid metal maintains its supercooled state to maintain its liquid form. Once triggered solidification, it proceeds rapidly, forming an amorphous solid.

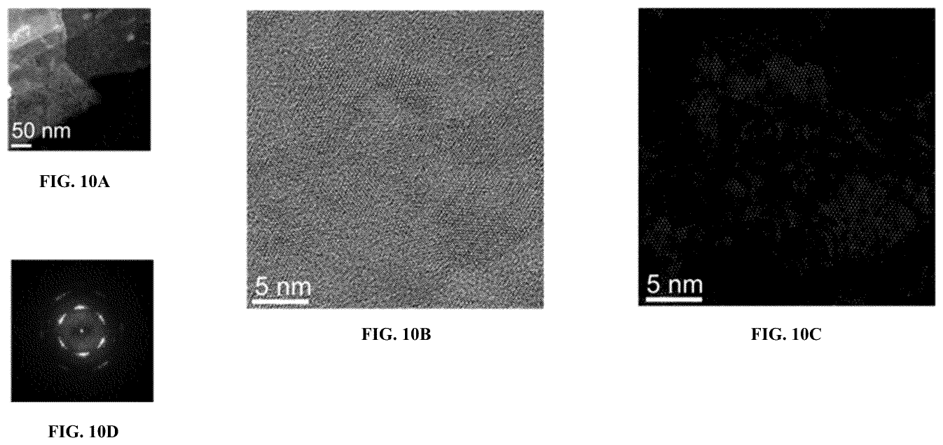

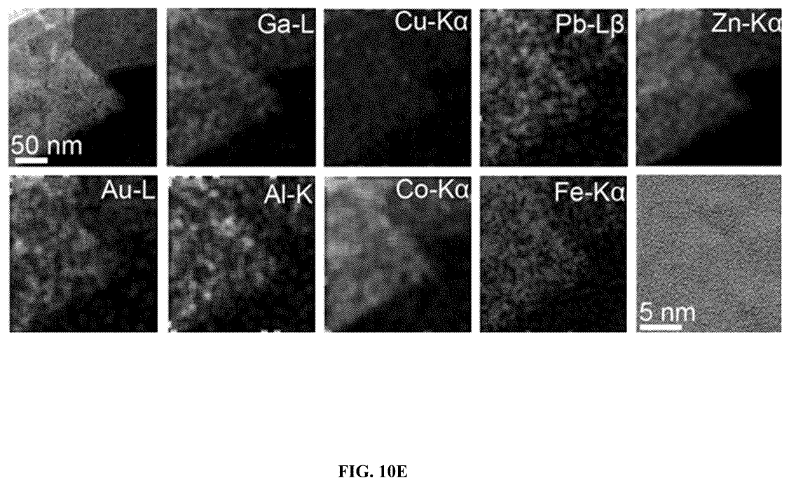

The precise control over the crystallinity of these HEAs confirms the presence of distinct supercooled states and the varied solidification rates during isothermal solidification synthesis. In contrast to the rapid cooling solidification synthesis methods, the isothermal solidification provides the opportunity to control the crystallinity and morphology of HEAs (Table 3). Atomic size, electronegativity, lattice constant, and preferred structure of the metallic elements Cu, Ga, Pd, Pt, Au, and Pb are described in Table 4. The molar ratio of elements in the HEAs of FIGS. 7B-7E is described in Table 5. Notably, precise control is achieved over the crystallinity of HEAs, successfully synthesizing mesocrystalline HEAs for the first time (see FIGS. 9A-9D, 10A-10E).

TABLE 3
Mixing enthalpy among the metal elements
Cu, Ga, Pd, Pt, Au, and Pb

| | Cu | Ga | Pd | Pt | Au | Pb |
|---|---|---|---|---|---|---|
| Cu | | 1 | −14 | −12 | −9 | 15 |
| Ga | 1 | | −42 | −38 | −19 | 5 |
| Pd | −14 | −42 | | 2 | 0 | −18 |
| Pt | −12 | −38 | 2 | | 4 | −5 |
| Au | −9 | −19 | 0 | 4 | | 2 |
| Pb | 15 | 5 | −18 | −5 | 2 | |

TABLE 4
Atomic size, electronegativity, lattice constant, and preferred
structure of the metallic elements Cu, Ga, Pd, Pt, Au, and Pb

| | Ga | Cu | Au | Pt | Pd | Pb |
|---|---|---|---|---|---|---|
| Atomic size | 136 | 145 | 174 | 177 | 169 | 154 |
| (pm) | | | | | | |
| Electronegativity | 1.81 | 1.9 | 2.54 | 2.28 | 2.2 | 2.33 |
| Lattice | 451.97 | 361.49, | 407.82, | 392.42, | 389.07, | 495.08, |
| | 766.33 | 361.49, | 407.82, | 392.42, | 389.07, | 495.08, |
| | 452.6 | 361.49 | 407.82 | 392.42 | 389.07 | 495.08 |
| Preferred | Base | FCC | FCC | FCC | FCC | FCC |
| structure | Orthorhombic | | | | | |

TABLE 5
The molar ratio of elements in the HEAs of FIGS. 7B-7E

| HEA | Ga | Cu | Pd | Pt | Au | Pb |
|---|---|---|---|---|---|---|
| Single crystal | 37.8% | 14.2% | 24.3% | 5.2% | 8.1% | 10.4% |
| (FIG. 7B) | | | | | | |
| Meso-crystal | 16.0% | 35.8% | 25.9% | 12.6% | 1.8% | 7.9% |
| (FIG. 7C) | | | | | | |
| Polycrystal | 0% | 43.1% | 27.1% | 3.7% | 17.0% | 9.1% |
| (FIG. 7D) | | | | | | |
| Amorphous | 6.7% | 30.4% | 36.0% | 14.7% | 4.0% | 8.2% |
| (FIG. 7E) | | | | | | |

### Example 4. Diversified Synthesis of HEAs

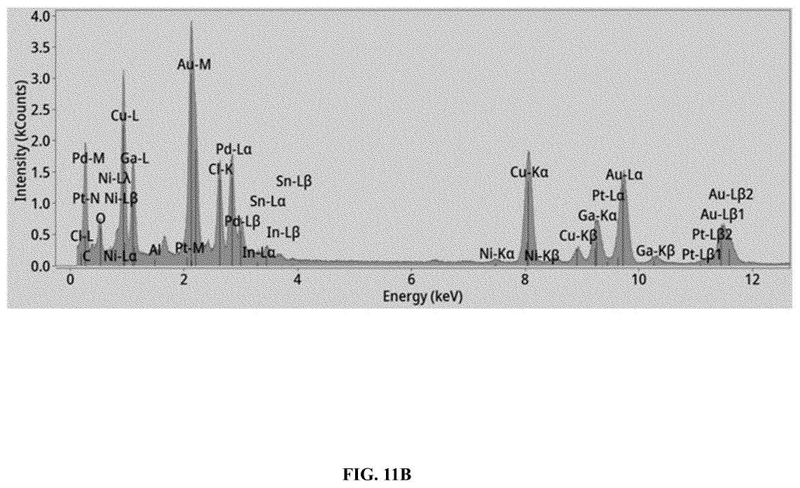

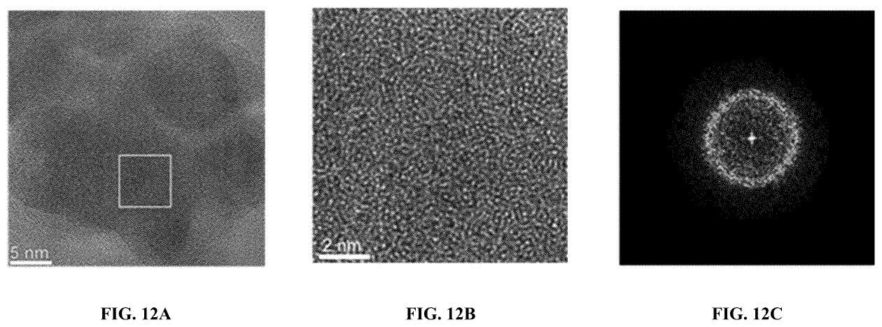

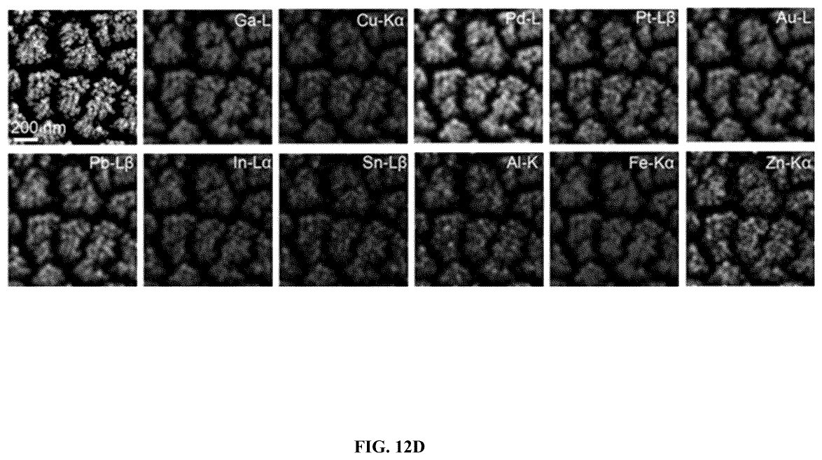

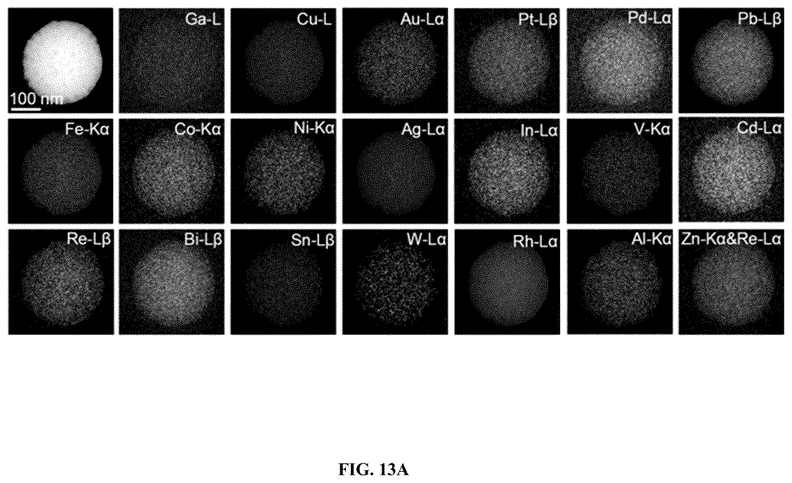

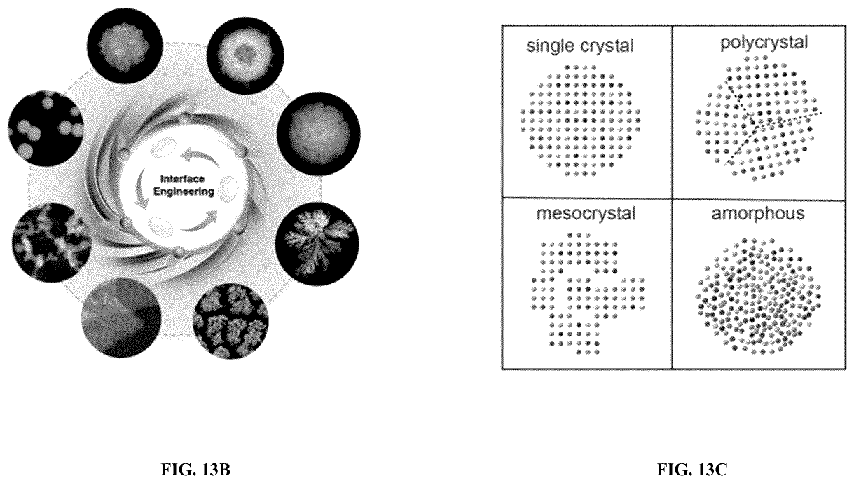

The isothermal solidification strategy demonstrates its robust capabilities for controlled synthesis of a diverse array of HEA nanomaterials, beyond the HEA NPs. In terms of composition control, a broad range of metallic elements can be incorporated into the liquid Ga metal, successfully forming quinary, senary, septenary, octonary, nonary, decennary, and undecennary HEAs (FIGS. 7A-7E, 11A-11B, 12A-12D). Additionally, Ga can be completely consumed to produce Ga-free HEAs (FIG. 7D, 11A-11B). As illustrated in FIG. 13A and Table 6, synthesized HEAs with more than 20 distinct elements, each possessing unique crystal structures, melting points, and atomic radii were synthesized. This capability highlights the versatility in generating a broad spectrum of HEA-NPs with diverse elemental combinations (FIG. 13A). HRTEM and EDS confirm the compositional homogeneity of these nanoparticles, showing no phase or elemental segregation (FIGS. 14A-14B).

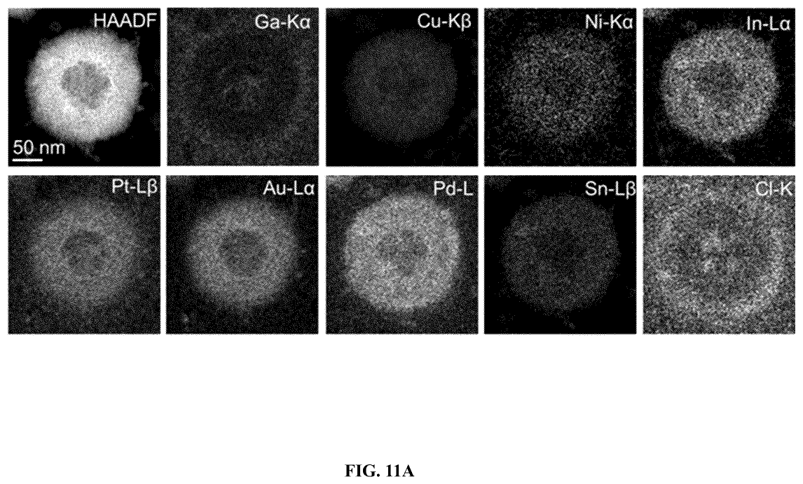

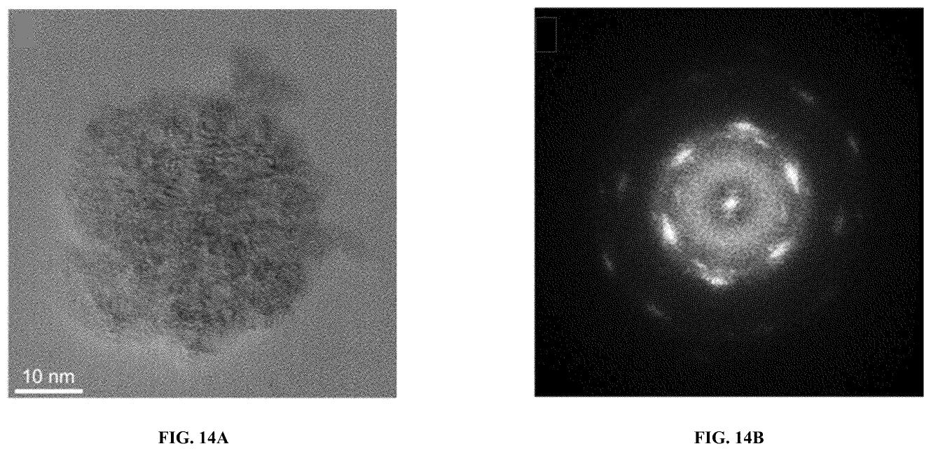

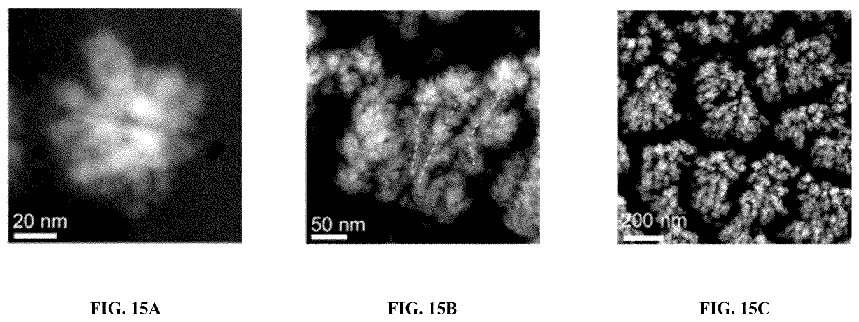

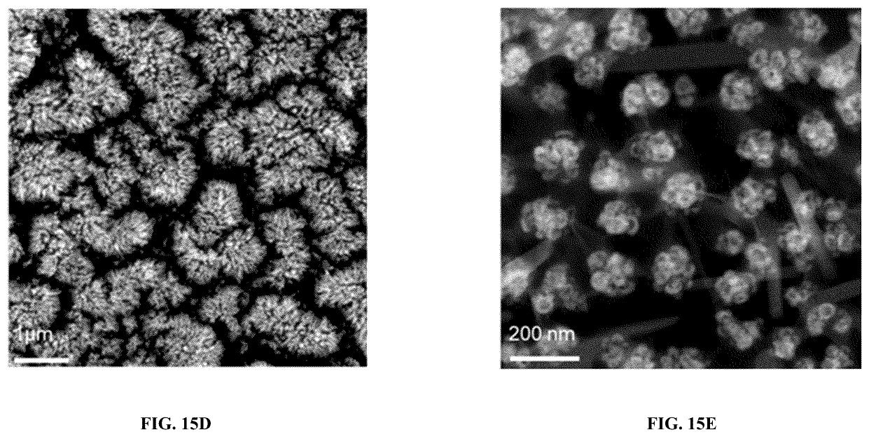

In addition to the mixing of diverse elements, the morphology and crystallinity of these HEAs can also be tuned, similar to the HEAs nanoparticles in FIGS. 7A-7E. By adjusting the reaction kinetics at liquid-liquid interfaces, a spectrum of structures spanning from zero-dimension (0D) to three-dimension (3D), can be synthesized, including solid, porous, hollow spheres, nanoflowers, nano dendrites, 2-dimension (2D) porous nanosheets, as well as 3D networks and hierarchical structures (FIGS. 13B, 11A-11B, 12A-12D, 15A-15E, 16A-16D).

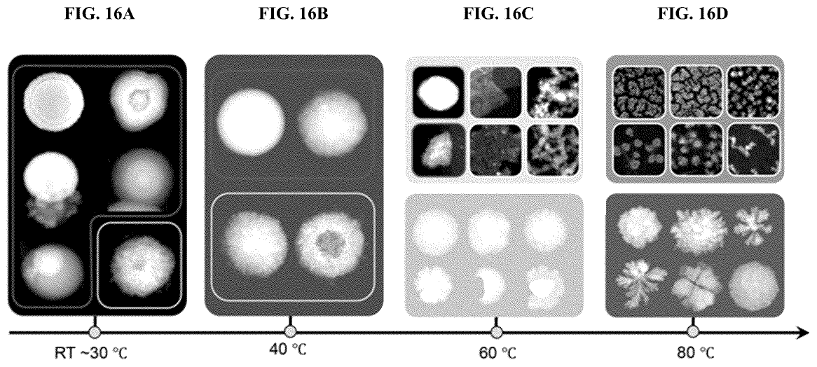

HEA-NPs with OD morphology (including solid, porous, flower-like nanoparticles) are typically obtained by utilizing spherical liquid metal precursors (as opposed to flakes of Ga) (FIGS. 16A-16D). At room temperature to 30° C. (FIG. 16A), when liquid Ga metal is used as precursor (marked by red outline), the resulting HEA-NPs tend to form phase-separated structures resembling egg-yolk and core-shell configurations. To synthesize nanoparticles in FIG. 16A, sphere liquid Ga (marked with red outline) or liquid Ga alloy (marked with yellow outline) were utilized as precursors. Additionally, HCl was introduced into the metal salt solution to eliminate the surface oxide of the Ga and Ga alloy particles.

By increasing the temperature to 40° C., HEA-NPs with solid sphere shapes can be achieved (FIG. 7B, marked by red outline in FIG. 16B). Further increasing the temperature to 60° C. and 80° C., HEA-NPs with porous spherical, flower-like, dendritic, and snowflake-like morphologies can be obtained (FIGS. 7C, 7D, 16D, 16F). This implies that raising the reaction temperature may enhance the uniform distribution of elements, formation of porous structures, and more diversified morphology in HEAs. In FIG. 16C, spherical shape (marked with indigo outline), irregular shape (marked with green outline), and 2D-film (marked with white outline) liquid Ga/Ga alloy precursors were employed, without the addition of HCl in the metal salt solution, and the reaction temperature is 60° C. In FIG. 16D, 2D-film liquid Ga/Ga alloy precursors were used and the reaction temperature is 80° C.

Interestingly, by using liquid Ga alloy instead of pure Ga precursor, HEA-NPs with porous structure can be obtained at 40° C. and even RT (highlighted by yellow outline in FIGS. 16A, 16B). Employing a liquid alloy precursor with a lower melting point yields similar effects as increasing the reaction temperature. This may be attributed to the lower melting point of the liquid Ga alloy further promotes the reduction reaction at the interfaces and the foreign metal atoms mixing. At the elevated temperatures (e.g., 60° C. or above), the impact of the liquid metal precursor is not notably pronounced, and both liquid Ga and liquid Ga-based alloys can yield porous or more diversified structures (FIGS. 7C, 7D, 16C lower panel, 16D lower panel).

Without the addition of HCl to the metal salt solution, the formation of HEAs at low temperatures (e.g., RT, and 40° C.) is hindered, as the oxide on the surface of the liquid metal acts as a passivation layer blocking the interface reaction. However, increasing the temperature can resolve this issue, allowing for the formation of HEAs with various morphologies (FIGS. 16C upper panel, 16D upper panel). We further find that ellipsoidal HEA-NPs are generated when spherical liquid metal precursors are employed (marked by indigo outline in FIG. 16C upper panel), HEAs with irregular shapes are obtained as irregular metal precursors are used (marked by green outline in FIG. 16C upper panel), and 2D film metal precursors are utilized to synthesize 2D nanosheets, 2D networks, 3D hierarchical structures, and some other intricate structures (marked by white outline in FIGS. 16C upper panel, 16D upper panel). Accompanying the morphological changes, the crystallinity can also be modified, enabling the synthesis of HEAs with single-crystalline, mesocrystalline, polycrystalline, and amorphous structures depending on the rate of isothermal solidification (FIGS. 7A-7E, 10A-10E, 11A-11B, 12A-12D, 13C). Table 6. Molar ratios of elements in the HEA (20 elements) corresponding to FIG. 13A

| Ga | Cu | Au | Pt | Pd | Pb | Fe | Co | Ni | Ag |
|---|---|---|---|---|---|---|---|---|---|
| 7.6% | 11.7% | 12.3% | 1.5% | 20.5% | 12.7% | 0.8% | 0.5% | 0.1% | 0.7% |
| In | V | Cd | Re | Bi | Sn | W | Rh | Al | Zn |
| 2.0% | 0.1% | 0.2% | 0.9% | 0.2% | 0.2% | 0.2% | 27.1% | 0.6% | 0.1% |

### Summary

The Examples provided herein verified an isothermal solidification strategy for the synthesis of HEAs with controlled crystallinity, morphology, and composition at low temperatures (room temperature to 80° C.). By directing the metal ion reduction reactions to the liquid-liquid interfaces, the foreign metal mixing rate is significantly enhanced. The fast metal mixing combined with the rapid Ga consumption effectively induce liquid alloys with high concentration of solute metal above the thermodynamic solubility limitation at low temperatures. The gas bubble-enhanced mixing and fluctuations of crystallization during isothermal solidification highlight an unexplored pathway to kinetically trap the high entropy state. The strategy provided herein broadens the scope of HEA synthesis and discovery, allowing the creation of previously unattainable HEAs with diverse structural configurations. The liquid-liquid interface reaction enables unhindered solidification, resulting in intricate solidification patterns at RT with promising applications, such as 3D printing of metals, catalysis, batteries, etc. Further exploration of the diverse HEAs has the potential to expand their applications across broader fields, spanning material science, chemistry, and biomedicine.

### Materials and Methods

### Chemicals

All chemicals used in this study were commercially available, and no further purification was required. These include Gallium (Ga; 99.99%), indium (In; 99.99%), tin (Sn; 99.999%), zinc (Zn; 99.8%), aluminum (Al; 99%), vanadium (III) chloride (VCl₃; 97%), cadmium chloride (CdCl₂; 99.99%), iron (III) chloride hexahydrate (FcCl₃·6H₂O; 98.0%-102%), cobalt (II) chloride hexahydrate (CoCl₂·6H₂O; 98%), nickel (II) chloride hexahydrate (NiCl₃·6H₂O; 99.9%), copper (II) chloride dihydrate (CuCl₂·2H₂O; 99.0%), zinc chloride (ZnCl₂; 98%), lead (II) chloride (PbCl₂; 99.999%), palladium (II) chloride (PdCl₂; 99%), platinum (II) chloride (PtCl₂; 99%), rhodium (II) chloride hydrate (RhCl₃·xH₂O; 38-40%), bismuth (III) chloride (BiCl₃; 99.99%), tungsten (VI) chloride (WCl₆; 99.9%), gold (III) chloride hydrate (HAuCl₄·xH₂O; ˜50% Au basis), silver nitrate (AgNO₃; 99.0%), 1-dodecanethiol (98%), 2-propanol (99.5%), acetone (CH₃COCH₃; 99.9%), and hydrochloric acid (HCl; 37%) were purchased from Sigma-Aldrich. Rhenium (III) chloride (ReCl₃; 61.4-65.9% Re) was purchased from Thermo Scientific Chemicals. To prepare the solutions, an ultrapure purification system (Milli-Q advantage A10) was used, which produced deionized water with a resistance of 18.2 MΩ cm.

### Preparation of Ga and Ga Alloy Nanoparticle Precursors

Two methods were used for the synthesis of Ga NPs. The first approach involves the synthesis of Ga NPs using a previously reported sonication technique (Yamaguchi, A. et al. Angew. Chem. Int. Ed 2015, 54, 12809-12813). Specifically, a mixture of Ga (100 mg, 1.43 mmol), 1-dodecanethiol (289 mg, 1.43 mmol) and 2-propanol (10 mL) was placed in a vial and sonicated for 2 h. Then, the obtained NPs were separated by centrifugation and washed three times with acetone to remove the remaining 1-dodecanethiol. Finally, the Ga NPs were re-dispersed in acetone for storage.

The second method involves scratching liquid Ga metal onto a carbon film substrate to form irregular thin film flakes. These thin film flakes were remarkably stable due to the formation of oxide layers on the Ga surface. Subsequently, by immersing the Ga/Ga-oxide flakes coated substrate in a 0.1 M HCl aqueous solution for 3 seconds triggered a reaction with the oxide layer, transforming the irregular Ga/Ga-oxide thin film flakes into Ga metal nanoparticles.

Galinstan was prepared by mixing Ga, In, and Sn metals at 250° C. until complete melting. The weight ratio of Ga:In:Sn was 68.5:21.5:10.0. GISZ alloys were prepared by mixing Ga, In, Sn, and Zn metals with various compositions in quartz tubes under a vacuum of approximately 5×10−4 Pa and heated at 250° C. for several hours until complete melting in a thermostatic oil bath 32. After melting, the alloys were cooled to RT and transferred into sealed vials using a plastic transfer pipette for further use. We used the same scratching method to prepare Galinstan and GISZ nanoparticles with different film flakes. Furthermore, the Ga-based alloy-loaded substrate was immersed in a 0.1M HCl aqueous solution for 3 seconds to get Galinstan and GISZ nanoparticles. After all nanoparticle formation, the sample was gently placed into deionized water to remove chloride for further use.

### Ga—Cu and Cu—Pd Binary Alloys

First, a commercial Au TEM grid coated with a carbon film was used as the substrate. A thin layer of liquid gallium metal was applied to the carbon film side by gentle scratching. Subsequently, the Ga-loaded TEM grid was immersed in a 0.1M HCl aqueous solution for 3 seconds. The HCl removed the native oxide layer on the Ga surface, allowing the liquid gallium to spontaneously break into numerous nanoparticles due to surface tension. The Au grid, now loaded with Ga nanoparticles, was thoroughly rinsed with deionized water to remove residual chloride ions and then dried. It was then placed on an IKA RCT magnetic hotplate, heated and maintained at a constant temperature of 60° C. A drop of CuCl₂ aqueous solution was added and allowed to react for two minutes. The resulting sample was washed again with deionized water, yielding Ga—Cu binary alloy particles as shown in FIG. 1D.

For the synthesis of Cu—Pd binary alloy nanoparticles (FIG. 1E), Ga particles were heated and maintained at 80° C. An aqueous solution of PdCl₂ was used in place of CuCl₂. All other experimental conditions and procedures were identical to those used for the synthesis of the Ga—Cu alloy.

### Preparation of Single Crystal GaCuPdPtAuPb HEA Nanoparticles

To synthesize GaCuPdPtAuPb high entropy alloy (HEA) nanoparticles, a nickel TEM grid coated with a carbon film was used as the substrate to eliminate any potential elemental interference from the grid during alloy formation. Ga nanoparticles were prepared using the second method (scratching method) to load on the substrate. The Ga particles were then heated and maintained at 60° C. on an IKA RCT magnetic hotplate. Subsequently, 0.1 M mixing aqueous solutions of CuCl₂, PbCl₂, PdCl₂, PtCl₂, and HAuCl₄ were dropped onto the carbon film and allowed to react for two minutes. The resulting sample was rinsed thoroughly with deionized water to obtain the single-crystalline high entropy alloy nanoparticles shown in FIG. 1F.

### Preparation of GaCuPdPtAuPb HEA With Tunable Morphologies and Structures

To prepare GaCuPdPtAuPb HEA with adjustable morphology and structure, the scratching method was used to form Ga nanoparticle precursor on a nickel TEM grid coated with a carbon film. The TEM grid loaded with Ga nanoparticles was heated to 40° C., after which a 0.1 M mixed aqueous solution containing HCl, CuCl₂, PbCl₂, PdCl₂, PtCl₂, and HAuCl₄ was dropped onto the carbon film and allowed to react for two minutes. The resulting sample was thoroughly rinsed with deionized water to yield the single-crystalline high entropy alloy nanoparticles shown in FIG. 7B. While keeping the reaction steps and conditions unchanged, only the heating temperature of the TEM grid was adjusted to 60° C. and 80° C. This led to the formation of GaCuPdPtAuPb HEA particles with a mesocrystalline structure at 60° C. (FIG. 7C), and CuPdPtAuPb HEA nanoparticles with a polycrystalline structure at 80° C. (FIG. 7E). If the other reaction conditions are kept constant and the salt concentration is doubled relative to the conditions in FIG. 7B, an amorphous GaCuPdPtAuPb alloy can be obtained (FIG. 7F).

### HEA Nanomaterial Preparation

To prepare the other HEA-NPs, carbon-supported TEM grids containing Ga, Galinstan, and GISZ alloy NPs were heated on an IKA RCT magnetic hotplate stirrer at RT, 40, 60, or 80° C. for 2 minutes. Various TEM carbon film grids were selected depending on the synthesis of different HEAs to better assess the influence of the TEM grid on experimental outcomes. Then, a drop of a mixture of various metal salt solutions (0.1 M for each salt) was added to the grid, with or without 0.1 M HCl. After one minute of reaction, the remaining liquid was removed and washed away the residual salt with deionized water. Then, the sample was loaded into a transmission electron microscope for characterization.

### Material Characterizations

The TEM characterizations were conducted using an image-corrected FEI ThemIS microscope operating at 60-300 kV. The microscope is equipped for fast EDS mapping and S/TEM imaging. All TEM and HRTEM were captured using an FEI Ceta2 camera. For EDS spectra and mapping, an FEI EDS detector with four windowless SDDs was employed. It provides a solid angle of 0.7 steradians and 140 eV energy resolution, enabling elemental mapping with high signal-to-noise ratio. During the TEM characterization process, we selected different TEM grids, washers, and clips based on the element combinations of the HEA.

### In Situ Liquid Cell Experiment for HEA-NP Formation

To study the alloying mechanisms of liquid metal with foreign metal source in the liquid phase environment, carbon film liquid cells were used in this experiment. First, the liquid GISZ alloy was deposited onto a carbon-supported gold grid by the scratching method. Next, the grid was swiftly immersed in a 0.1 M HCl solution for 1 second, followed by rinsing with deionized water, effectively forming GISZ nanoparticles onto the carbon-supported grid. After drying, 100 nl of CuCl₂·2H₂O aqueous solution (0.1 M) and 10 nl of 0.1M HCl solution were dropped onto the GISZ-loaded carbon film. The wet grid was covered with another grid. After the liquid cell was assembled, it was loaded into the microscope for imaging. An FEI ThemIS 60-300 STEM/TEM with Cs-corrector was used for in situ imaging, and a beam current density of ˜100 e⁻ nm⁻² s⁻¹ was used for the study.

### EDS Analysis

EDS analysis was performed by Velox software. To accurately determine the distribution of each metal element in high entropy alloy materials, we extract EDS maps from their distinct (i.e., non-overlapping) characteristic X-ray signals to avoid mutual interference between different element signal sources. We use specific characteristic X-rays peaks of different elements to identify the source signals for high entropy alloys. For example, we use the Ga-L, Cu-Kα, Pd-L, Pt-Lβ, Au-L, and Pb-Lβ signals to show elemental distribution within HEA-NPs. If there are overlapping signal peaks that cannot be distinguished, the characteristic X-ray peaks of two elements together were used to label the mapping signal source.

The section headings used herein are for organizational purposes only and are not to be construed as limiting the subject matter described in any way.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. A method of producing an alloy, the method comprising:
providing gallium (Ga) or gallium alloy particles in a liquid state; and
contacting the gallium or gallium alloy particles with a metal salt solution comprising one or more metal precursors,
thereby initiating a reaction to produce an alloy.

2. The method of claim 1, wherein the gallium or gallium alloy particles are loaded on a substrate.

3. The method of claim 2, wherein the substrate is a carbon substrate.

4. The method of claim 1, wherein the reaction comprises isothermal solidification.

5. The method of claim 1, wherein the reaction is conducted at a temperature of about 25° C. to about 80° C.

6. The method of claim 5, wherein the reaction is conducted at about 40° C., at about 60° C., or at about 80° C.

7. The method of claim 1, wherein the reaction is conducted for about 1 minute to 3 minutes.

8. The method of claim 1, wherein the gallium or gallium alloy particles are nanoparticles.

9. The method of claim 1, wherein the metal salt solution comprises HCl.

10. The method of claim 1, wherein the one or more metal precursors are HₓMCl_{y}, wherein M is a metal.

11. The method of claim 10, wherein the metal (M) of the one or more metal precursors comprise at least 2, 3, 4, 5, 6, 7, 8, or 9 different metals selected from the group consisting of K, V, Cr, Mn, Fe, Co, Ni, Cu, Zn, Ru, Rh, Nd, Cd, In, Sn, Sb, Cs, Nd, Re, Pt, Au, and Pb.

12. The method of claim 10, wherein the one or more metal precursors consist essentially of Cu, Pb, Pd, Pt, and Au.

13. The method of claim 1, wherein the alloy comprises a high entropy alloy (HEA).

14. The method of claim 13, wherein the HEA comprises GaCuPdPtAuPb, GaCuPbZnAuFeCoAl, or AiFeCuPtZnPbInSnPdAuGa.

15. The method of claim 1, wherein the alloy does not comprise Ga.

16. The method of claim 1, wherein the alloy is about 5 nanometers to 1 micron in size.

17. The method of claim 1, wherein the alloy comprises a single crystal, comprises a mesocrystal, is polycrystalline, or is amorphous.

18. The method of claim 1, further comprising:
adjusting the reaction temperature, the reaction kinetics, the interface between the gallium or gallium alloy particles and the metal salt solution, or the composition of the gallium or gallium alloy particles or the metal salt solution, to adjust the elemental composition, the size, the crystallinity, or the morphology of the alloy.

19. An alloy produced by the method of claim 1.

20. A high entropy alloy comprising a high entropy mesocrystal or is free of gallium (Ga).
